(19) United States
(12) Patent Application Publication
(10) Pub. No.: US 2016/0322385 A1
(43) Pub. Date: Nov. 3, 2016

(54) SUBSTRATE BIAS FOR FIELD-EFFECT TRANSISTOR DEVICES

(71) Applicant: SKYWORKS SOLUTIONS, INC., Woburn, MA (US)

(72) Inventors: Hanching FUH, Allston, MA (US); Steven Christopher SPRINKLE, Hampstead, NH (US); David Scott WHITEFIELD, Andover, MA (US); Jerod F. MASON, Bedford, MA (US)

(21) Appl. No.: 15/085,980

(22) Filed: Mar. 30, 2016

Related U.S. Application Data
(60) Provisional application No. 62/140,945, filed on Mar. 31, 2015.

(51) Int. Cl. H01L 27/12; H01L 29/06; H01L 23/66; H01L 21/762; H01L 23/528; H01L 23/498; H01L 25/065; H01L 21/84; H01L 29/10; H01L 23/522

(52) U.S. Cl. CPC H01L 27/1203; H01L 29/1087; H01L 29/0649; H01L 23/66; H01L 23/5226; H01L 23/528; H01L 23/49838; H01L 25/0655; H01L 21/84; H01L 21/76251

(57) ABSTRACT

Substrate bias for field-effect transistor (FET) devices. In some embodiments, a radio-frequency (RF) device can include a FET implemented over a substrate layer, and an electrical connection implemented to provide a substrate bias node associated with the substrate layer. The RF device can further include a non-grounding circuit connected to the substrate bias node to adjust RF performance of the FET. In some embodiments, the electrical connection can include a pattern of one or more conductive features in electrical contact with the substrate layer.

### CROSS-REFERENCE TO RELATED APPLICATION(S)

This application claims priority to U.S. Provisional Application No. 62/140,945 filed Mar. 31, 2015, entitled SUBSTRATE BIAS FOR SOI DEVICES, the disclosure of which is hereby expressly incorporated by reference herein in its respective entirety.

### BACKGROUND

1. Field

The present disclosure relates to biasing of field-effect transistor (FET) devices such as silicon-on-insulator (SOI) devices.

2. Description of the Related Art

In electronics applications, field-effect transistors (FETs) can be utilized as switches. Such switches can allow, for example, routing of radio-frequency (RF) signals in wireless devices.

### SUMMARY

In accordance with a number of implementations, the present disclosure relates to a radio-frequency (RF) device that includes a field-effect transistor (FET) implemented over a substrate layer, and an electrical connection implemented to provide a substrate bias node associated with the substrate layer. The RF device further includes a non-grounding circuit connected to the substrate bias node to adjust RF performance of the FET.

In some embodiments, the adjustment of the RF performance can include a dynamic adjustment or a static adjustment.

In some embodiments, the RF device can be configured as an RF switch with the FET providing ON and OFF functionalities of the RF switch. The RF performance can include, for example, harmonic generation, intermodulation distortion (IMD) such as a second-order IMD (IMD2) or a third-order IMD (IMD3), insertion loss, isolation, linearity, voltage breakdown characteristic, noise figure, phase, and/or impedance.

In some embodiments, the substrate layer can be a part of a silicon-on-insulator (SOI) substrate. The substrate layer can be a silicon handle layer. The substrate can be a handle layer that includes an electrically-insulating material such as glass, borosilicon glass, fused quartz, sapphire, or silicon carbide.

In some embodiments, the FET can be implemented over an insulator layer of the SOI substrate. The insulator layer can include a buried oxide (BOX) layer. The FET can be formed with an active silicon layer of the SOI substrate.

In some embodiments, the electrical connection can include one or more conductive features implemented through the insulator layer. The one or more conductive features can include, for example, one or more conductive vias, one or more conductive trenches, or any combination thereof.

In some embodiments, the non-grounding circuit can include a bias network configured to provide a bias signal to the substrate layer. The bias signal can include a DC voltage. The bias network can include a resistance through which the DC voltage is provided to the substrate layer.

In some embodiments, the non-grounding circuit can include a coupling circuit configured to couple the substrate node with one or more nodes associated with a gate, a source, a drain and a body of the FET.

In some embodiments, the coupling circuit can include a coupling path between the substrate node and the gate node. The coupling path between the substrate node and the gate node can include a resistance. The coupling path between the substrate node and the gate node can include a phase-shifting circuit such as a capacitance in series with the resistance. The coupling path between the substrate node and the gate node can include a diode in series with the resistance. The coupling path between the substrate node and the gate node can include a phase-shifting circuit such as a capacitance in parallel with the diode.

In some embodiments, the coupling circuit can include a coupling path between the substrate node and the body node. The coupling path between the substrate node and the body node can include a phase-shifting circuit. The coupling path between the substrate node and the body node can include a diode. The coupling path between the substrate node and the body node can include a phase-shifting circuit in parallel with the diode.

In some embodiments, the coupling circuit can include a coupling path between the substrate node and the source node. The coupling path between the substrate node and the source node can include a phase-shifting circuit. The coupling path between the substrate node and the source node can includes diode. The coupling path between the substrate node and the source node can include a phase-shifting circuit in parallel with the diode.

In some embodiments, the coupling circuit can include a coupling path between the substrate node and the drain node. The coupling path between the substrate node and the drain node can include a phase-shifting circuit. The coupling path between the substrate node and the drain node can include a diode. The coupling path between the substrate node and the drain node can include a phase-shifting circuit in parallel with the diode.

In some embodiments, the non-grounding circuit can further include a bias network configured to provide a bias voltage to the substrate layer.

In some embodiments, the SOI substrate can be configured such that the substrate layer is in direct engagement with an insulator layer. In some embodiments, the SOI substrate can include an interface layer implemented between the substrate layer and an insulator layer. Such an interface layer can include, for example, a trap-rich layer.

In some embodiments, the SOI substrate can be configured such that substrate layer includes a plurality of doped regions at or near a surface under an insulator layer. Such doped regions can include, for example, amorphous and high resistivity properties.

In some teachings, the present disclosure relates to a method for fabricating a radio-frequency (RF) device. The method includes forming a field-effect transistor (FET) over a substrate layer, electrically connecting the substrate layer to a substrate node, and coupling a non-grounding circuit to the substrate node to adjust RF performance of the FET.

In some embodiments, the substrate layer can be a part of a silicon-on-insulator (SOI) substrate. The substrate layer can be a silicon handle layer. The substrate can be a handle layer that includes an electrically-insulating material such as glass, borosilicon glass, fused quartz, sapphire, or silicon carbide.

In some embodiments, the FET can be implemented over an insulator layer of the SOI substrate. The insulator layer can include a buried oxide (BOX) layer. The FET can be formed with an active silicon layer of the SOI substrate.

In some embodiments, the electrical connecting can include forming one or more conductive features through the insulator layer. The one or more conductive features can include one or more conductive vias, one or more conductive trenches, or any combination thereof.

In some embodiments, the non-grounding circuit can include a bias network configured to provide a bias signal to the substrate layer. The bias network can include a resistance through which the DC voltage is provided to the substrate layer.

In some embodiments, the non-grounding circuit can include a coupling circuit configured to couple the substrate node with one or more nodes associated with a gate, a source, a drain and a body of the FET. The coupling circuit can include a coupling path between the substrate node and the gate node. The coupling circuit can include a coupling path between the substrate node and the body node. The coupling circuit can include a coupling path between the substrate node and the source node. The coupling circuit can include a coupling path between the substrate node and the drain node.

According to some implementations, the present disclosure relates to a radio-frequency (RF) switch device that includes a die having a substrate layer, and an RF core implemented on the die. The RF core includes a plurality of field-effect transistors (FETs) configured to provide switching functionality. The RF switch device further includes an energy management (EM) core implemented on the die. The EM core is configured to facilitate the switching functionality of the RF core. The RF switch device further includes a pattern of one or more conductive features in electrical contact with the substrate layer of the die to provide a substrate node. The pattern is implemented relative to a circuit element associated with the RF switch device.

In some embodiments, the die can be a silicon-on-insulator (SOI) die. The pattern of one or more conductive features can include one or more conductive vias implemented through a buried oxide (BOX) layer of the SOI die, one or more conductive trenches implemented through the BOX layer of the SOI die, or any combination thereof.

In some embodiments, the pattern of one or more conductive features can be configured to at least partially surround the circuit element. In some embodiments, the circuit element can include the RF core and the EM core. In some embodiments, the circuit element can include the RF core.

In some embodiments, the RF core can include a switch circuit having one or more poles and one or more throws, with each path between the one or more poles and the one or more throws including one or more FETs configured to operate as a switch. In some embodiments, the circuit element can include the switch circuit. In some embodiments, the circuit element can include each path of the switch circuit. In some embodiments, the circuit element can include each FET of a given path.

In some embodiments, the one or more FETs in a given path can include a plurality of FETs implemented in a stack configuration to operate as a switching arm. In some embodiments, the circuit element can include the stack. In some embodiments, the circuit element can include each FET.

In some embodiments, the pattern can be configured to substantially surround the circuit element. Such a pattern can be dimensioned as, for example, a rectangle around the circuit element.

In some embodiments, the pattern can be configured to partially surround the circuit element. The pattern is configured to, for example, cover three sides of a rectangular shape about the circuit element, cover two sides (e.g., two adjacent sides or two opposing sides) of a rectangular shape about the circuit element, cover one side of a rectangular shape about the circuit element, or include one or more conductive features positioned at one or more discrete locations relative to the circuit element.

In some embodiments, the pattern can include a first group of one or more conductive features and a second group of one or more conductive features. Each of the first group and the second group can be implemented relative to the circuit element. In some embodiments, each of the first and second groups can be configured to be coupled to a separate substrate biasing network. In some embodiments, both of the first and second groups can be configured to be coupled to common substrate biasing network.

In some teachings, the present disclosure relates to a method for fabricating a radio-frequency (RF) switch device. The method includes providing or forming a die including a substrate layer, and implementing an RF core on the die. The RF core includes a plurality of field-effect transistors (FETs) configured to provide switching functionality. The method further includes implementing an energy management (EM) core on the die. The EM core is configured to facilitate the switching functionality of the RF core. The method further includes forming a pattern of one or more conductive features in electrical contact with the substrate layer of the die to provide a substrate node. The pattern is implemented relative to a circuit element associated with the RF switch device.

In some embodiments, the providing or forming of the die can include providing or forming a wafer having the substrate layer. The wafer can be a silicon-on-insulator (SOI) wafer. The pattern of one or more conductive features can include, for example, one or more conductive vias implemented through a buried oxide (BOX) layer of the SOI wafer for each RF switch device.

In some embodiments, the pattern of one or more conductive features can be configured to at least partially surround the circuit element. In some embodiments, the circuit element can include the RF core and the EM core. In some embodiments, the circuit element can include the RF core.

In some embodiments, the RF core can include a switch circuit having one or more poles and one or more throws, with each path between the one or more poles and the one or more throws including one or more FETs configured to operate as a switch. The one or more FETs in a given path can include a plurality of FETs implemented in a stack configuration to operate as a switching arm. In some embodiments, the circuit element can include the stack. In some embodiments, the circuit element can include each FET.

In some embodiments, the pattern can be configured to substantially surround the circuit element. In some embodiments, the pattern can be configured to partially surround the circuit element. In some embodiments, the pattern can be configured to include one or more conductive features positioned at one or more discrete locations relative to the circuit element.

In some embodiments, the pattern can include a first group of one or more conductive features and a second group of one or more conductive features, with each of the first group and the second group being implemented relative to the circuit element. In some embodiments, each of the first and second groups can be configured to be coupled to a separate substrate biasing network. In some embodiments, both of the first and second groups can be configured to be coupled to common substrate biasing network.

In some implementations, the present disclosure relates to a radio-frequency (RF) module that includes a packaging substrate configured to receive a plurality of devices, and a switching device mounted on the packaging substrate. The switching device includes a field-effect transistor (FET) implemented over a substrate layer, and an electrical connection implemented to provide a substrate bias node associated with the substrate layer. The switching device further includes a non-grounding circuit connected to the substrate bias node to adjust RF performance of the FET.

In some embodiments, the RF module can be a switch module. In some embodiments, the substrate layer can be part of a silicon-on-insulator (SOI) substrate.

According to some implementations, the present disclosure relates to a radio-frequency (RF) switch module that includes a packaging substrate configured to receive a plurality of devices, and a switch die mounted on the packaging substrate. The die includes a substrate layer, and an RF core having a plurality of field-effect transistors (FETs) configured to provide switching functionality. The switch die further includes an energy management (EM) core configured to facilitate the switching functionality of the RF core. The switch die further includes a pattern of one or more conductive features in electrical contact with the substrate layer of the die to provide a substrate node. The pattern is implemented relative to a circuit element associated with the RF switch device.

In some embodiments, the switch die can include a silicon-on-insulator (SOI) substrate.

In some embodiments, the switching functionality can include an M-pole-N-throw (MPNT) functionality, with each of the quantities M and N being a positive integer. The MPNT functionality can includes a single-pole-double-throw (SPDT) functionality, with the single pole configured as an antenna node, and each of the double throws configured as a node for a signal path capable of either or both of transmit (Tx) and receive (Rx) operations. The MPNT functionality can include a double-pole-double-throw (DPDT) functionality, with each of the double poles configured as an antenna node, and each of the double throws configured as a node for a signal path capable of either or both of transmit (Tx) and receive (Rx) operations.

In some teachings, the present disclosure relates to a wireless device that includes a transceiver configured to process radio-frequency (RF) signals, and an RF module in communication with the transceiver. The RF module includes a switching device having a field-effect transistor (FET) implemented over a substrate layer, and an electrical connection implemented to provide a substrate bias node. The switching device further includes a non-grounding circuit connected to the substrate bias node and configured to adjust RF performance of the FET. The wireless device further includes an antenna in communication with the RF module. The antenna is configured to facilitate transmitting and/or receiving of the RF signals.

In some implementations, the present disclosure relates to a wireless device that includes a transceiver configured to process radio-frequency (RF) signals, and an RF module in communication with the transceiver. The RF module includes a switch die having a substrate layer, and an RF core having a plurality of field-effect transistors (FETs) configured to provide switching functionality. The switch die further includes an energy management (EM) core configured to facilitate the switching functionality of the RF core. The switch die further includes a pattern of one or more conductive features in electrical contact with the substrate layer of the die to provide a substrate node. The pattern is implemented relative to a circuit element associated with the RF switch die. The wireless device further includes an antenna in communication with the RF module. The antenna is configured to facilitate transmitting and/or receiving of the RF signals.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows an example of a field-effect transistor (FET) device having an active FET implemented on a substrate, and a region below the active FET configured to include one or more features to provide one or more desirable operating functionalities for the active FET.

FIG. 2 shows an example of a FET device having an active FET implemented on a substrate, and a region above the active FET configured to include one or more features to provide one or more desirable operating functionalities for the active FET.

FIG. 3 shows that in some embodiments, a FET device can include both of the regions of FIGS. 1 and 2 relative an active FET.

FIG. 4 shows an example FET device implemented as an individual silicon-on-insulator (SOI) unit.

FIG. 5 shows that in some embodiments, a plurality of individual SOI devices similar to the example SOI device of FIG. 4 can be implemented on a wafer.

FIG. 6A shows an example wafer assembly having a first wafer and a second wafer positioned over the first wafer.

FIG. 6B shows an unassembled view of the first and second wafers of the example of FIG. 6A.

FIG. 7 shows a terminal representation of an SOI FET having nodes associated with a gate, a source, a drain, a body, and a substrate.

FIGS. 8A and 8B show side sectional and plan views, respectively, of an example SOI FET device having a node for its substrate.

FIG. 9 shows a side sectional view of an SOI substrate that can be utilized to form an SOI FET device having an electrical connection for a substrate layer.

FIG. 10 shows a side sectional view of an SOI FET device having an electrical connection for a substrate layer.

FIG. 11 shows an example SOI FET device that is similar to the example of FIG. 10, but in which a trap-rich layer is substantially absent.

FIG. 12 shows that in some embodiments, an electrical connection to a substrate can be implemented without being coupled to other portions of an active FET.

FIG. 13 shows that in some embodiments, a handle wafer can include a plurality of doped regions implemented to provide one or more functionalities similar to a trap-rich interface layer in the example of FIG. 10.

FIG. 14 shows the same configuration as in the example of FIG. 13, as well as an example of how a given conductive feature can interact with a FET through the handle wafer.

FIG. 15 shows a process that can be implemented to fabricate an SOI FET device having one or more features as described herein.

FIG. 16 shows examples of various stages of the fabrication process of FIG. 15.

FIG. 17 shows that in some embodiments, an SOI FET device having one or more features as described herein can have its substrate node biased by a substrate bias network.

FIG. 18 shows an example of a radio-frequency (RF) switching configuration having an RF core and an energy management (EM) core.

FIG. 19 shows an example of the RF core of FIG. 18, in which each of the switch arms includes a stack of FET devices.

FIG. 20 shows an example of the biasing configuration of FIG. 17, implemented in a switch arm having a stack of FETs as described in reference to FIG. 19.

FIG. 21 shows that a pattern of one or more conductive features can be implemented to be electrically connected to a substrate of an SOI FET device.

FIG. 22 shows an example configuration in which a pattern of conductive features for substrate connection can generally form a ring shaped perimeter substantially around an entire die having an RF core and an EM core.

FIG. 23 shows an example configuration in which a pattern of conductive features for substrate connection can generally form a ring shaped distribution implemented substantially around each of an RF core and an EM core of a switching die.

FIG. 24 shows an example configuration in which a pattern of conductive features for substrate connection can generally form a ring shaped distribution implemented substantially around an assembly of series arms and shunt arms.

FIG. 25 shows an example configuration in which a pattern of conductive features for substrate connection can generally form a ring shaped distribution implemented substantially around each of series arms and shunt arms.

FIG. 26 shows an example configuration in which a pattern of conductive features for substrate connection can generally form a ring shaped distribution implemented substantially around each FET in a given arm.

FIGS. 27A-27E show non-limiting examples of patterns of conductive features for substrate connection that can be implemented around a circuit element.

FIGS. 28A and 28B show that in some embodiments, there may be more than one pattern of conductive features implemented relative a circuit element.

FIG. 29 shows an example in which a substrate node of an SOI FET device can be electrically connected to a substrate bias network.

FIG. 30 shows another example in which a substrate node of an SOI FET device can be electrically connected to a substrate bias network.

FIG. 31 shows an example in which a substrate node of an SOI FET device can be electrically connected to a gate node of the SOI FET device.

FIG. 32 shows an example in which a substrate node of an SOI FET device can be electrically connected to a gate node of the SOI FET device through a phase-shift circuit.

FIG. 33 shows an example in which a substrate node of an SOI FET device can be electrically connected to a gate node of the SOI FET device 100 through a phase-shift circuit, similar to the example of FIG. 32, and in which a substrate bias network can be configured to allow application of a DC control voltage to the substrate node.

FIG. 34A shows an example that is similar to the example of FIG. 31, but with a diode D in series with a resistance R.

FIG. 34B shows that in some embodiments, the polarity of the diode D can be reversed from the example of FIG. 34A.

FIG. 35 shows an example that is similar to the example of FIG. 32, but with a diode D in parallel with a phase-shifting circuit.

FIG. 36 shows an example that is similar to the example of FIG. 31, but with a diode D in series with a resistance R.

FIG. 37 shows an example that is similar to the example of FIG. 35, but with biasing.

FIG. 38 shows an SOI FET device having a substrate connection as described herein.

FIGS. 39A-39D show examples of how a substrate node of an SOI FET device can be coupled to other nodes of the SOI FET device.

FIGS. 40A-40D show examples of how a substrate node of an SOI FET device can be coupled to other nodes of the SOI FET device through a phase-shifting circuit.

FIGS. 41A-41D show examples that are similar to the examples of FIGS. 39A-39D, and in which a bias signal can be applied to the substrate node.

FIGS. 42A-42D show examples that are similar to the examples of FIGS. 40A-40D, and in which a bias signal can be applied to the substrate node.

FIGS. 43A-43D show examples of how a substrate node of an SOI FET device can be coupled to other nodes of the SOI FET device through a diode D.

FIGS. 44A-44D show examples of how a substrate node of an SOI FET device can be coupled to other nodes of the SOI FET device through a diode D and a phase-shifting circuit.

FIGS. 45A-45D show examples that are similar to the examples of FIGS. 43A-43D, and in which a bias signal can be applied to the substrate node.

FIGS. 46A-46D show examples that are similar to the examples of FIGS. 44A-44D, and in which a bias signal can be applied to the substrate node.

FIG. 47 shows a switch assembly implemented in a single-pole-single-throw (SPST) configuration utilizing an SOI FET device.

FIG. 48 shows that in some embodiments, the SOI FET device of FIG. 47 can include a substrate biasing/coupling feature as described herein.

FIG. 49 shows an example of how two SPST switches having one or more features as described herein can be utilized to form a switch assembly having a single-pole-double-throw (SPDT) configuration.

FIG. 50 shows that the switch assembly of FIG. 49 can be utilized in an antenna switch configuration.

FIG. 51 shows an example of how three SPST switches having one or more features as described herein can be utilized to form a switch assembly having a single-pole-triple-throw (SP3T) configuration.

FIG. 52 shows that the switch assembly of FIG. 51 can be utilized in an antenna switch configuration.

FIG. 53 shows an example of how four SPST switches having one or more features as described herein can be utilized to form a switch assembly having a double-pole-double-throw (DPDT) configuration.

FIG. 54 shows that the switch assembly of FIG. 53 can be utilized in an antenna switch configuration.

FIG. 55 shows an example of how nine SPST switches having one or more features as described herein can be utilized to form a switch assembly having a 3-pole-3-throw (3P3T) configuration.

FIG. 56 shows that the switch assembly of FIG. 55 can be utilized in an antenna switch configuration.

FIGS. 57A-57E show examples of how a DPDT switching configuration such as the examples of FIGS. 53 and 54 can be operated to provide different signal routing functionalities.

FIGS. 58A-58D depict non-limiting examples of switching circuits and bias/coupling circuits as described herein can be implemented on one or more semiconductor die.

FIGS. 59A and 59B show plan and side views, respectively, of a packaged module having one or more features as described herein.

FIG. 60 shows a schematic diagram of an example switching configuration that can be implemented in the module of FIGS. 59A and 59B.

FIG. 61 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

### Introduction

Disclosed herein are various examples of a field-effect transistor (FET) device having one or more regions relative to an active FET portion configured to provide a desired operating condition for the active FET. In such various examples, terms such as FET device, active FET portion, and FET are sometimes used interchangeably, with each other, or some combination thereof. Accordingly, such interchangeable usage of terms should be understood in appropriate contexts.

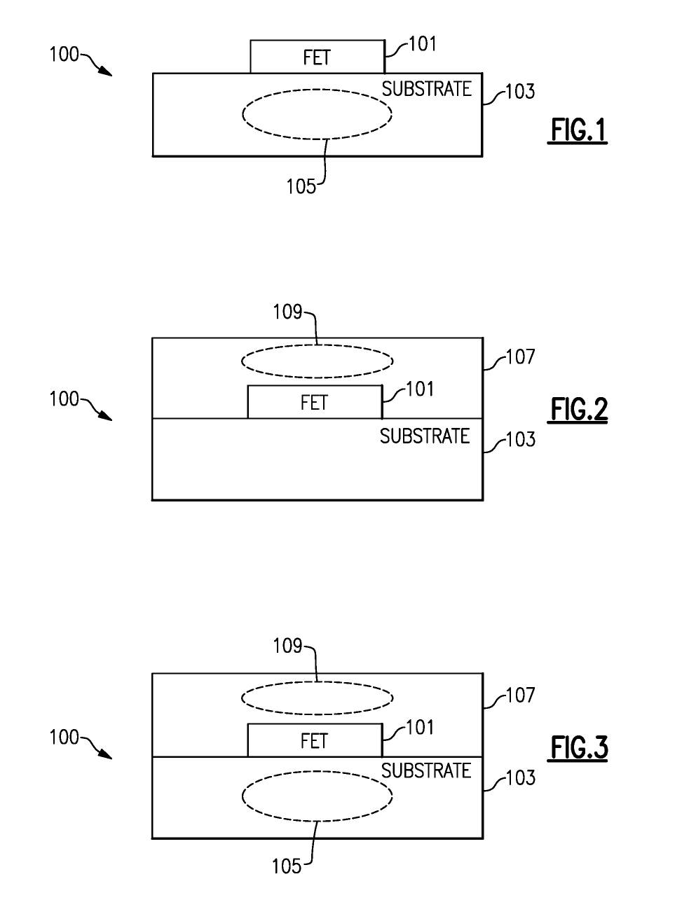

FIG. 1 shows an example of a FET device 100 having an active FET 101 implemented on a substrate 103. As described herein, such a substrate can include one or more layers configured to facilitate, for example, operating functionality of the active FET, processing functionality for fabrication and support of the active FET, etc. For example, if the FET device 100 is implemented as a silicon-on-Insulator (SOI) device, the substrate 103 can include an insulator layer such as a buried oxide (BOX) layer, an interface layer, and a handle wafer layer.

FIG. 1 further shows that in some embodiments, a region 105 below the active FET 101 can be configured to include one or more features to provide one or more desirable operating functionalities for the active FET 101. For the purpose of description, it will be understood that relative positions above and below are in the example context of the active FET 101 being oriented above the substrate 103 as shown. Accordingly, some or all of the region 105 can be implemented within the substrate 103. Further, it will be understood that the region 105 may or may not overlap with the active FET 101 when viewed from above (e.g., in a plan view).

FIG. 2 shows an example of a FET device 100 having an active FET 101 implemented on a substrate 103. As described herein, such a substrate can include one or more layers configured to facilitate, for example, operating functionality of the active FET 100, processing functionality for fabrication and support of the active FET 100, etc. For example, if the FET device 100 is implemented as a silicon-on-Insulator (SOI) device, the substrate 103 can include an insulator layer such as a buried oxide (BOX) layer, an interface layer, and a handle wafer layer.

In the example of FIG. 2, the FET device 100 is shown to further include an upper layer 107 implemented over the substrate 103. In some embodiments, such an upper layer can include, for example, a plurality of layers of metal routing features and dielectric layers to facilitate, for example, connectivity functionality for the active FET 100.

FIG. 2 further shows that in some embodiments, a region 109 above the active FET 101 can be configured to include one or more features to provide one or more desirable operating functionalities for the active FET 101. Accordingly, some or all of the region 109 can be implemented within the upper layer 107. Further, it will be understood that the region 109 may or may not overlap with the active FET 101 when viewed from above (e.g., in a plan view).

FIG. 3 shows an example of a FET device 100 having an active FET 101 implemented on a substrate 103, and also having an upper layer 107. In some embodiments, the substrate 103 can include a region 105 similar to the example of FIG. 1, and the upper layer 107 can include a region 109 similar to the example of FIG. 2.

Examples related to some or all of the configurations of FIGS. 1-3 are described herein in greater detail.

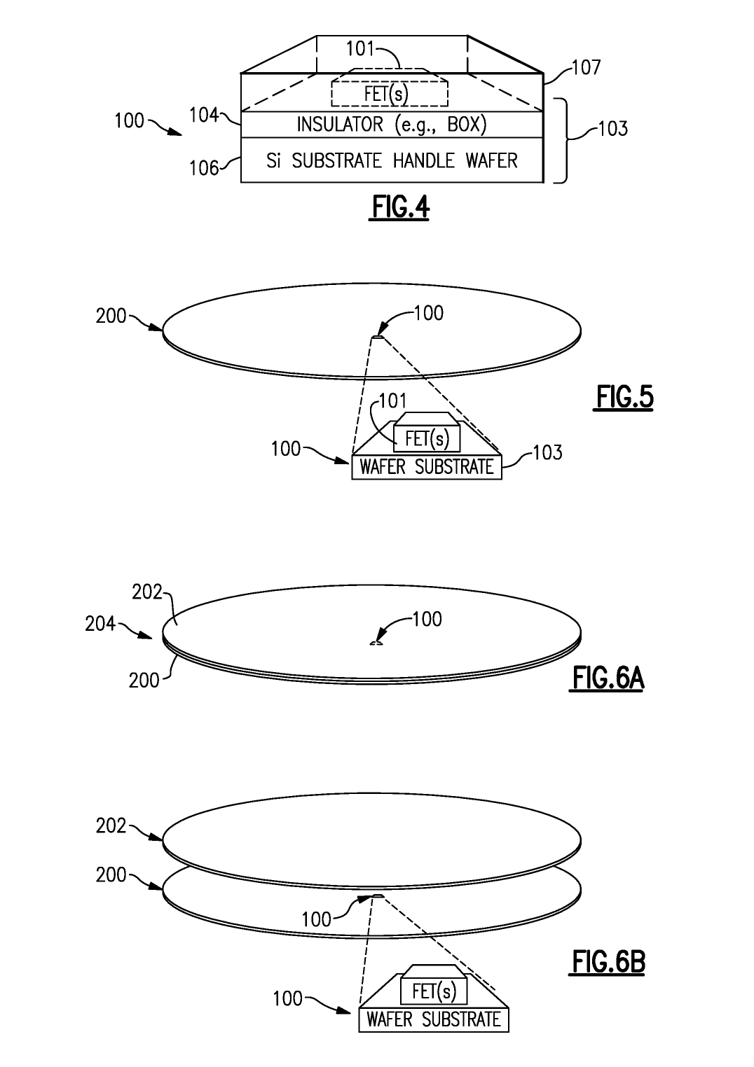

In the examples of FIGS. 1-3, the FET devices 100 are depicted as being individual units (e.g., as semiconductor die). FIGS. 4-6 show that in some embodiments, a plurality of FET devices having one or more features as described herein can be fabricated partially or fully in a wafer format, and then be singulated to provide such individual units.

For example, FIG. 4 shows an example FET device 100 implemented as an individual SOI unit. Such an individual SOI device can include one or more active FETs 101 implemented over an insulator such as a BOX layer 104 which is itself implemented over a handle layer such as a silicon (Si) substrate handle wafer 106. In the example of FIG. 4, the BOX layer 104 and the Si substrate handle wafer 106 can collectively form the substrate 103 of the examples of FIGS. 1-3, with or without the corresponding region 105.

In the example of FIG. 4, the individual SOI device 100 is shown to further include an upper layer 107. In some embodiments, such an upper layer can be the upper layer 103 of FIGS. 2 and 3, with or without the corresponding region 109.

FIG. 5 shows that in some embodiments, a plurality of individual SOI devices similar to the example SOI device 100 of FIG. 4 can be implemented on a wafer 200. As shown, such a wafer can include a wafer substrate 103 that includes a BOX layer 104 and a Si handle wafer layer 106 as described in reference to FIG. 4. As described herein, one or more active FETs can be implemented over such a wafer substrate.

In the example of FIG. 5, the SOI device 100 is shown without the upper layer (107 in FIG. 4). It will be understood that such a layer can be formed over the wafer substrate 103, be part of a second wafer, or any combination thereof.

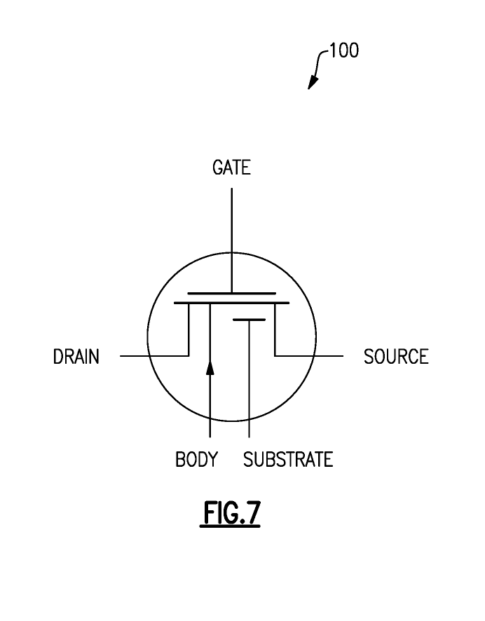

FIG. 6A shows an example wafer assembly 204 having a first wafer 200 and a second wafer 202 positioned over the first wafer 200. FIG. 6B shows an unassembled view of the first and second wafers 200, 202 of the example of FIG. 6A.

In some embodiments, the first wafer 200 can be similar to the wafer 200 of FIG. 5. Accordingly, the first wafer 200 can include a plurality of SOI devices 100 such as the example of FIG. 4. In some embodiments, the second wafer 202 can be configured to provide, for example, a region (e.g., 109 in FIGS. 2 and 3) over a FET of each SOI device 100, and/or to provide temporary or permanent handling wafer functionality for process steps involving the first wafer 200.

### Examples of SOI Implementation of FET Devices

Silicon-on-Insulator (SOI) process technology is utilized in many radio-frequency (RF) circuits, including those involving high performance, low loss, high linearity switches. In such RF switching circuits, performance advantage typically results from building a transistor in silicon, which sits on an insulator such as an insulating buried oxide (BOX). The BOX typically sits on a handle wafer, typically silicon, but can be glass, borosilicon glass, fused quartz, sapphire, silicon carbide, or any other electrically-insulating material.

Typically, an SOI transistor is viewed as a 4-terminal field-effect transistor (FET) device with gate, drain, source, and body terminals. However, an SOI FET can be represented as a 5-terminal device, with an addition of a substrate node. Such a substrate node can be biased and/or be coupled one or more other nodes of the transistor to, for example, improve both linearity and loss performance of the transistor. Various examples related to such a substrate node and biasing/coupling of the substrate node are described herein in greater detail. Although various examples are described in the context of RF switches, it will be understood that one or more features of the present disclosure can also be implemented in other applications involving FETs.

FIG. 7 shows a terminal representation of an SOI FET 100 having nodes associated with a gate, a source, a drain, a body, and a substrate. It will be understood that in some embodiments, the source and the drain can be reversed.

FIGS. 8A and 8B show side sectional and plan views of an example SOI FET device 100 having a node for its substrate. Such a substrate can be, for example, a silicon substrate associated with a handle wafer 106 as described herein. Although described in the context of such a handle wafer, it will be understood that the substrate does not necessarily need to have functionality associated with a handle wafer.

An insulator layer such as a BOX layer 104 is shown to be formed over the handle wafer 106, and a FET structure is shown to be formed based on an active silicon device 102 over the BOX layer 104. In various examples described herein, and as shown in FIGS. 8A and 8B, the FET structure can be configured as an NPN or PNP device.

In the example of FIGS. 8A and 8B, terminals for the gate, source, drain and body are shown to be configured and provided so as to allow operation of the FET. A substrate terminal is shown to be electrically connected to the substrate (e.g., handle wafer) 106 through an electrically conductive feature 108 extending through the BOX layer 104. Such an electrically conductive feature can include, for example, one or more conductive vias, one or more conductive trenches, or any combination thereof. Various examples of how such an electrically conductive feature can be implemented are described herein in greater detail.

In some embodiments, a substrate connection can be connected to ground to, for example, avoid an electrically floating condition associated with the substrate. Such a substrate connection for grounding typically includes a seal-ring implemented at an outermost perimeter of a given die.

In some embodiments, a substrate connection such as the example of FIGS. 8A and 8B can be utilized to bias the substrate 106, to couple the substrate with one or more nodes of the corresponding FET (e.g., to provide RF feedback), or any combination thereof. Such use of the substrate connection can be configured to, for example, improve RF performance and/or reduce cost by eliminating or reducing expensive handle-wafer treatment processes and layers. Such performance improvements can include, for example, improvements in linearity, loss and/or capacitance performance.

In some embodiments, the foregoing biasing of the substrate node can be, for example, selectively applied to achieve desired RF effects only when needed or desired. For example, bias points for the substrate node can be connected to envelope-tracking (ET) bias for power amplifier (PA) to achieve distortion cancellation effects.

In some embodiments, a substrate connection for providing the foregoing example functionalities can be implemented as a seal-ring configuration similar to the grounding configuration, or other connection configurations. Examples of such substrate connections are described herein in greater detail.

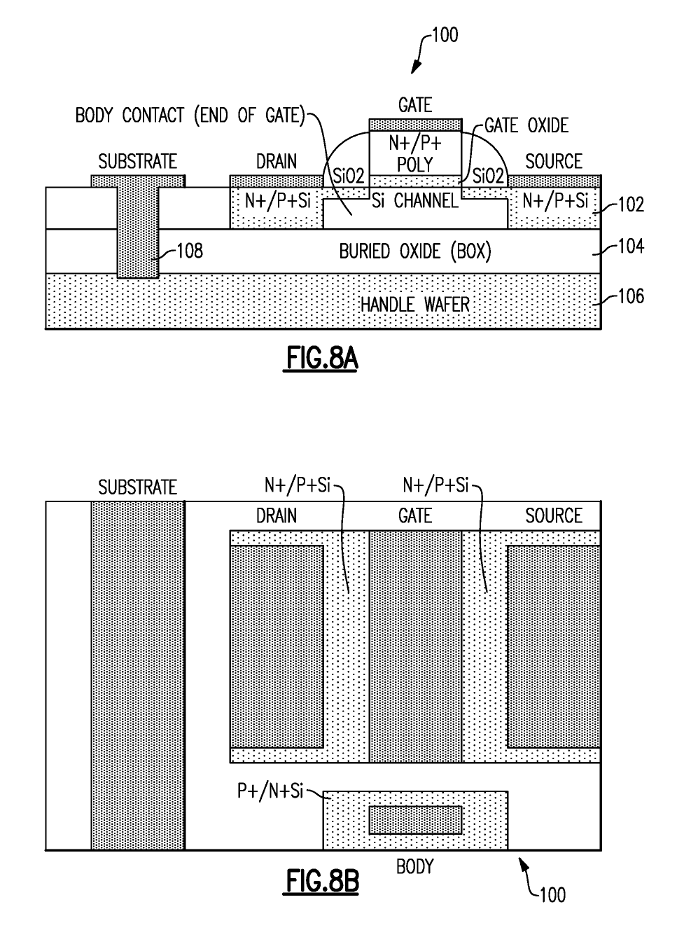

FIG. 9 shows a side sectional view of an SOI substrate 10 that can be utilized to form an SOI FET device 100 of FIG. 10 having an electrical connection for a substrate layer 106 (e.g., Si handle layer). In FIG. 9, an insulator layer such as a BOX layer 104 is shown to be formed over the Si handle layer 106. An active Si layer 12 is shown to be formed over the BOX layer 104. It will be understood that in some embodiments, the foregoing SOI substrate 10 of FIG. 9 can be implemented in a wafer format, and SOI FET devices having one or more features as described herein can be formed based on such a wafer.

In FIG. 10, an active Si device 102 is shown to be formed from the active Si layer 12 of FIG. 9. One or more electrically conductive features 108 such as vias are shown to be implemented through the BOX layer 104, relative to the active Si device 102. In some embodiments, such conductive features (108) can allow the Si handle layer 106 to be coupled to the active Si device (e.g., a FET), be biased, or any combination thereof. Such coupling and/or biasing can be facilitated by, for example, a metal stack 110. In some embodiments, such a metal stack can allow the conductive features 108 to be electrically connected to a terminal 112. In the example of FIG. 10, one or more passivation layers, one or more dielectric layers, or some combination thereof (collectively indicated as 114) can be formed to cover some or all of such a metal stack.

In some embodiments, a trap-rich layer 14 can be implemented between the BOX layer 104 and the Si handle layer 106. However, and as described herein, the electrical connection to the Si handle layer 106 through the conductive feature(s) 108 can eliminate or reduce the need for such a trap-rich layer which is typically present to control charge at an interface between the BOX layer 104 and the Si handle layer 106, and which can involve costly process steps.

Aside from the foregoing example of eliminating or reducing the need for a trap-rich layer, the electrical connection to the Si handle layer 106 can provide a number of advantageous features. For example, the conductive feature(s) 108 can allow forcing of excess charge at the BOX/Si handle interface to thereby reduce unwanted harmonics. In another example, excess charge can be removed through the conductive feature(s) 108 to thereby reduce the off-capacitance (Coff) of the SOI FET. In yet another example, the presence of the conductive feature(s) 108 can lower the threshold of the SOI FET to thereby reduce the on-resistance (Ron) of the SOI FET.

FIG. 11 shows an example FET device 100 that is similar to the example of FIG. 10, but in which a trap-rich layer (14 in FIG. 10) is substantially absent. Accordingly, in some embodiments, the BOX layer 104 and the Si handle layer 106 can be in substantially direct engagement with each other.

In the example of FIG. 11, the conductive features (e.g., vias) 108 are depicted as extending through the BOX layer 104 and contacting the Si handle layer 106 generally at the BOX/Si handle interface. It will be understood that in some embodiments, such conductive features can extend deeper into the Si handle layer 106.

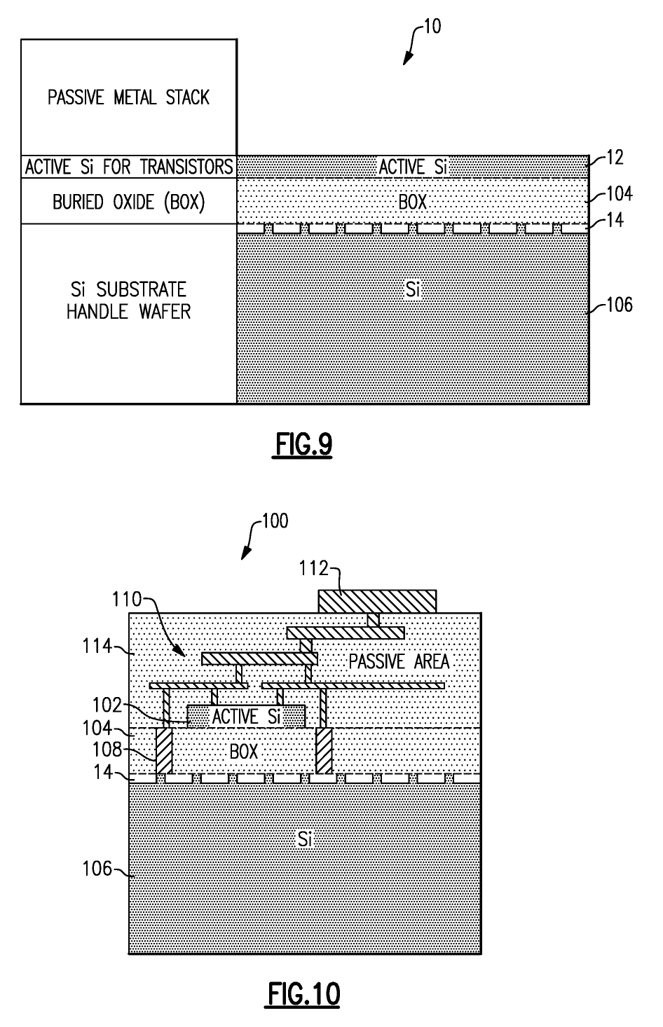

In the examples of FIGS. 10 and 11, the conductive features 108 are depicted as being coupled to other electrical connections associated with the active Si device 102. FIG. 12 shows that in some embodiments, an electrical connection to a substrate (e.g., Si handle layer 106) can be implemented without being coupled to such other electrical connections associated with the active Si device 102. For example, a conductive feature 108 such as a via is shown to extend through the BOX layer 104 so as to form a contact with the Si handle layer 106. The upper portion of the through-BOX conductive feature 108 is shown to be electrically connected to a terminal 113 that is separate from a terminal 112.

In some embodiments, the electrical connection between the separate terminal 113 and the Si handle layer 106 (through the conductive feature 108) can be configured to allow, for example, separate biasing of a region in the substrate (e.g., Si handle layer 106) to achieve a desired operating functionality for the active Si device 102. Such an electrical connection between the separate terminal 113 and the Si handle layer 106 is an example of a non-grounding configuration utilizing one or more through-BOX conductive features 108.

In the examples of FIGS. 10-12, the through-BOX conductive features (108) are depicted as either being coupled to electrical connections associated with the active Si device 102, or as being separate from such electrical connections. It will be understood that other configurations can also be implemented. For example, one or more through-BOX conductive features (108) can be coupled to one node of the active Si device 102 (e.g., source, drain or gate), but not other node(s). Non-limiting examples of circuit representations of such coupling (or non-coupling) between the substrate node and other nodes of the active Si device are disclosed herein in greater detail.

In the example of FIG. 10, the trap-rich layer 14 can be implemented as an interface layer between the BOX layer 104 and the Si handle layer 106, to provide one or more functionalities as described herein. In the examples of FIGS. 11 and 12, such a trap-rich interface layer 14 can be omitted as described herein.

FIG. 13 shows that in some embodiments, a handle wafer 106 (e.g., Si handle layer) can include a plurality of doped regions 117 implemented to provide one or more functionalities similar to a trap-rich interface layer (e.g., 14 in FIG. 10). Such doped regions can be, for example, generally amorphous and have relatively high resistivity when compared to other portions of the handle wafer 106.

In the example of FIG. 13, two FETs 102 and islands 115 are shown to be formed from an active Si layer 12 which is implemented over a BOX layer 104. The BOX layer is shown to be implemented over the handle wafer 106 having the doped regions 117. In some embodiments, such doped regions (117) can be implemented to be laterally positioned generally under gaps between the FETs 102 and/or the islands 115.

FIG. 13 further shows that in some embodiments, the handle wafer 106 having doped regions such as the foregoing doped regions 117 can be biased as described herein through one or more conductive features 108 such as vias. As described herein, such conductive features 108 can be coupled to other portions of FET(s), to a separate terminal, or any combination thereof, so as to provide biasing to the handle wafer substrate 106 to achieve one or more desired operating functionalities for the FET(s).

FIG. 14 shows the same configuration as in the example of FIG. 13, as well as an example of how a given conductive feature 108 can interact with a FET 102 through the handle wafer 106. For example, the BOX layer being interposed between the FET 102 and the handle wafer 106 can result in a capacitance C therebetween. Further, a resistance R can exist between the end of the conductive feature 108 and the BOX/handle wafer interface. Accordingly, a series RC coupling can be provided between the conductive feature 108 and the underside of the FET 102. Thus, providing a bias signal to handle wafer 106 through the conductive feature can provide a desirable operating environment for the FET 102 as described herein.

In the example of FIGS. 13 and 14, a given conductive feature 108 is depicted as being laterally separated from the nearest FET 102 so as to include at least one doped region 117 in the handle wafer 106. Accordingly, the resulting resistive path (with resistance R) can be relatively long. Thus, the resistance R can be a high resistance.

Referring to the examples of FIGS. 10-14, it is noted that in some embodiments, a given conductive feature 108 can be implemented so as to be laterally separated from the nearest FET 102 by a separation distance. Such a separation distance can be, for example, at least 1 μm, 2 μm, 3 μm, 4 μm, 5 μm, 6 μm, 7 μm, 8 μm, 9 μm, or 10 μm. In some embodiments, the separation distance can be in a range of 5 μm to 10 μm. For the purpose of description, it will be understood that such a separation distance can be, for example, a distance between the closest portions of the conductive feature 108 and the corresponding FET 102 in the active Si layer (12).

### Examples Related to Fabrication of SOI FET Devices

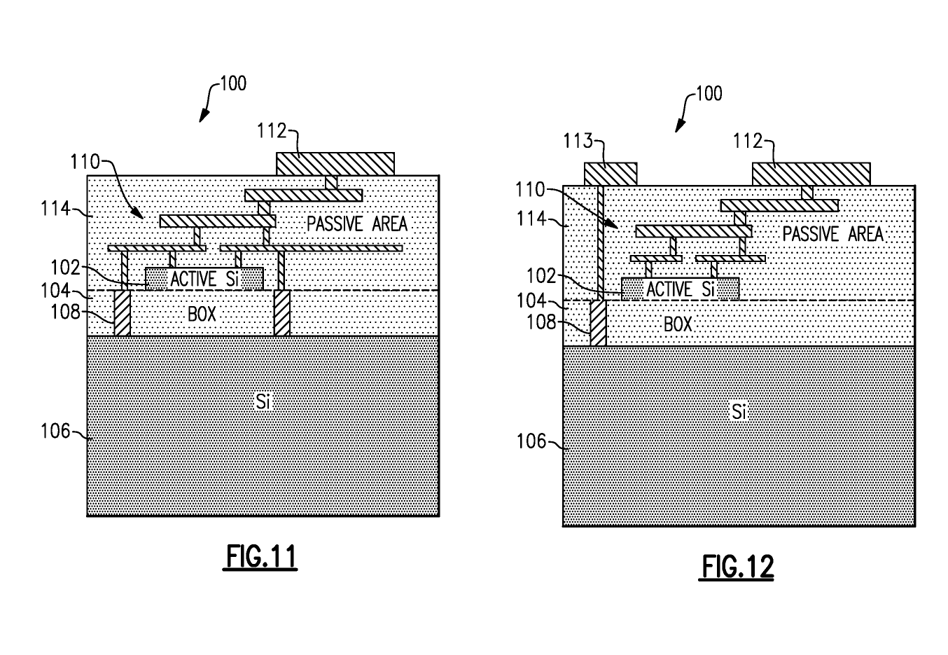

FIG. 15 shows a process 130 that can be implemented to fabricate an SOI FET device having one or more features as described herein. FIG. 16 shows examples of various stages of the fabrication process of FIG. 15.

In block 132 of FIG. 15, an SOI substrate can be formed or provided. In state 140 of FIG. 16, such an SOI substrate can include an Si substrate 106 such as an Si handle wafer, an oxide layer 104 over the Si substrate 106, and an active Si layer 12 over the oxide layer 104. Such an SOI substrate may or may not have a trap-rich layer (e.g., 14 in FIGS. 9 and 10) between the oxide layer 104 and the Si substrate 106. Similarly, such an SOI substrate may or may not have doped regions (e.g., 117 in FIG. 13) in the Si substrate 106.

In block 134 of FIG. 15, one or more FETs can be formed with the active Si layer. In state 142 of FIG. 16, such a FET is depicted as 101.

In block 136 of FIG. 15, one or more conductive features such as vias can be formed through the oxide layer, to the Si substrate, and relative to the FET(s). In state 144 of FIG. 16, such a conductive via is depicted as 108. As described herein, such an electrical connection through the oxide layer 104 to the Si substrate 106 can also be implemented utilizing other conductive features such as one or more conductive trenches.

In the example of FIGS. 15 and 16, it will be understood that blocks 134 and 136 may or may not be performed in the example sequence shown. In some embodiments, conductive feature(s) such as a deep trench can be formed and filled with poly prior to the formation of the FET(s). In some embodiments, such conductive feature(s) can be formed (e.g., cut and filled with a metal such as tungsten (W) after the formation of the FET(s). It will be understood that other variations in sequences associated with the example of FIGS. 15 and 16 can also be implemented.

In block 138 of FIG. 15, electrical connections can be formed for the conductive vias and the FET(s). In state 146 of FIG. 16, such electrical connections are depicted as a metallization stack collectively indicated as 110. Such a metal stack can electrically connect the FET(s) 101 and the conductive vias 108 to one or more terminals 112. In the example state 146 of FIG. 16, a passivation layer 114 is shown to be formed to cover some or all of the metallization stack 110.

Examples Related to Substrate Biasing and/or Coupling of SOI FET Devices

FIG. 17 shows that in some embodiments, an SOI FET device 100 having one or more features as described herein can have its substrate node biased by a substrate bias network 152. Various examples related to such a substrate bias network are described herein in greater detail.

In the example of FIG. 17, other nodes such as the gate and the body of the SOI FET device 100 can also be biased by their respective networks. Among others, examples related to such gate and body bias networks can be found in PCT Publication No. WO 2014/011510 entitled CIRCUITS, DEVICES, METHODS AND COMBINATIONS RELATED TO SILICON-ON-INSULATOR BASED RADIO-FREQUENCY SWITCHES, the disclosure of which is hereby expressly incorporated by reference herein in its entirety.

FIGS. 18-20 show that in some embodiments, SOI FETs having one or more features as described herein can be implemented in RF switching applications.

FIG. 18 shows an example of an RF switching configuration 160 having an RF core 162 and an energy management (EM) core 164. Additional details concerning such RF and EM cores can be found in the above-referenced PCT Publication No. WO 2014/011510. The example RF core 162 of FIG. 18 is shown as a single-pole-double-throw (SPDT) configuration in which series arms of transistors 100a, 100b are arranged between a pole and first and second throws, respectively. Nodes associated with the first and second throws are shown to be coupled to ground through their respective shunt arms of transistors 100c, 100d.

In the example of FIG. 18, some or all of the transistors 100a-100d can include electrical connections to respective substrates as described herein. Such electrical connections to the substrates can be utilized to provide bias to the substrates and/or provide coupling with other portion(s) of the respective transistors.

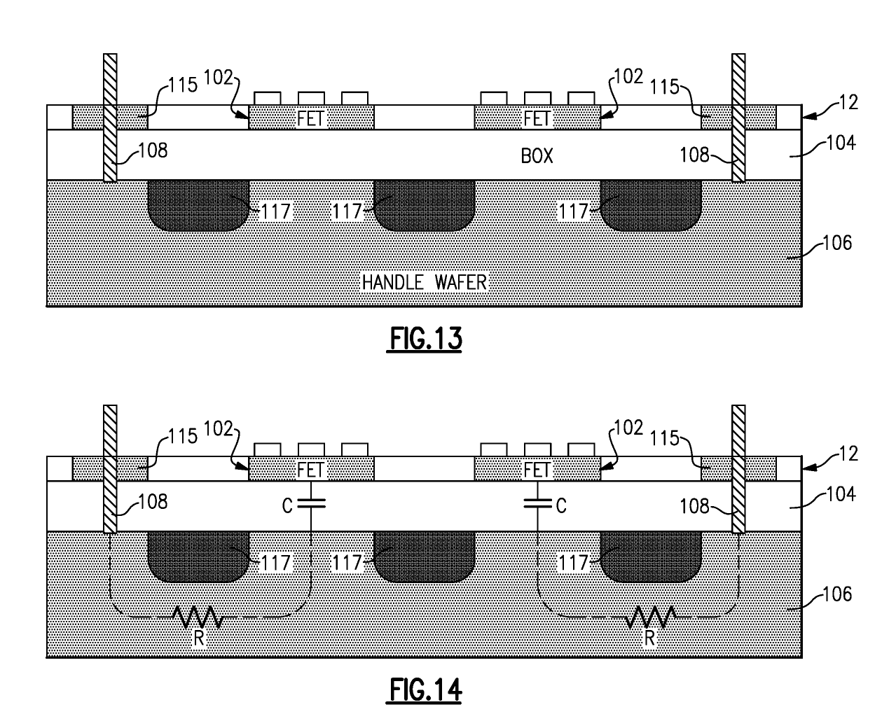

FIG. 19 shows an example of the RF core 162 of FIG. 18, in which each of the switch arms 100a-100d includes a stack of FET devices. For the purpose of description, each FET in such a stack can be referred to as a FET, the stack itself can be collectively referred to as a FET, or some combination thereof can also be referred to as a FET. In the example of FIG. 19, each FET in the corresponding stack is shown to include a substrate node connection as described herein. It will be understood that some or all of the FET devices in the RF core 162 can include such substrate node connections.

FIG. 20 shows an example of the biasing configuration 150 of FIG. 17, implemented in a switch arm having a stack of FETs 100 as described in reference to FIG. 19. In the example of FIG. 20, each FET in the stack can be biased with a separate substrate bias network 152, the FETs in the stack can be biased with a plurality of substrate bias networks 152, all of the FETs in the stack can be biased with a common substrate bias network, or any combination thereof. Such possible variations can also apply to gate biasing (156) and body biasing (154).

FIG. 21 shows that a pattern 170 of one or more conductive features 108 can be implemented to be electrically connected to a substrate (e.g., Si handle wafer) of an SOI FET device. In some embodiments, such a pattern of conductive features can also be electrically connected (depicted as 172) to a substrate bias network 152. In some embodiments, and as described herein, such a pattern of conductive features can be electrically connected to another node of the SOI FET device, with or without the substrate bias network 152.

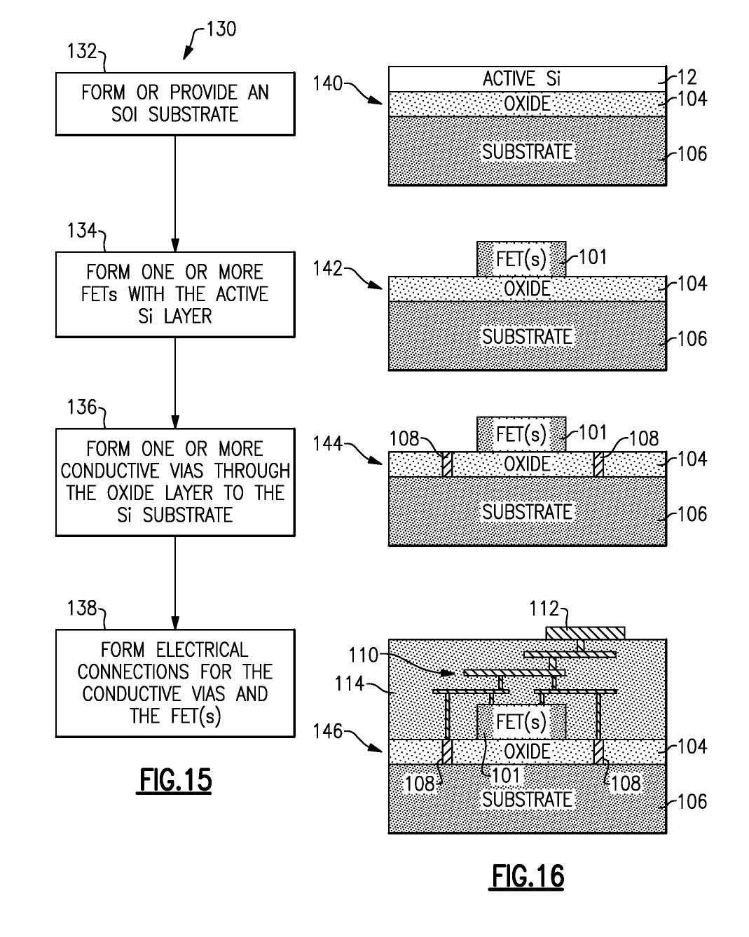

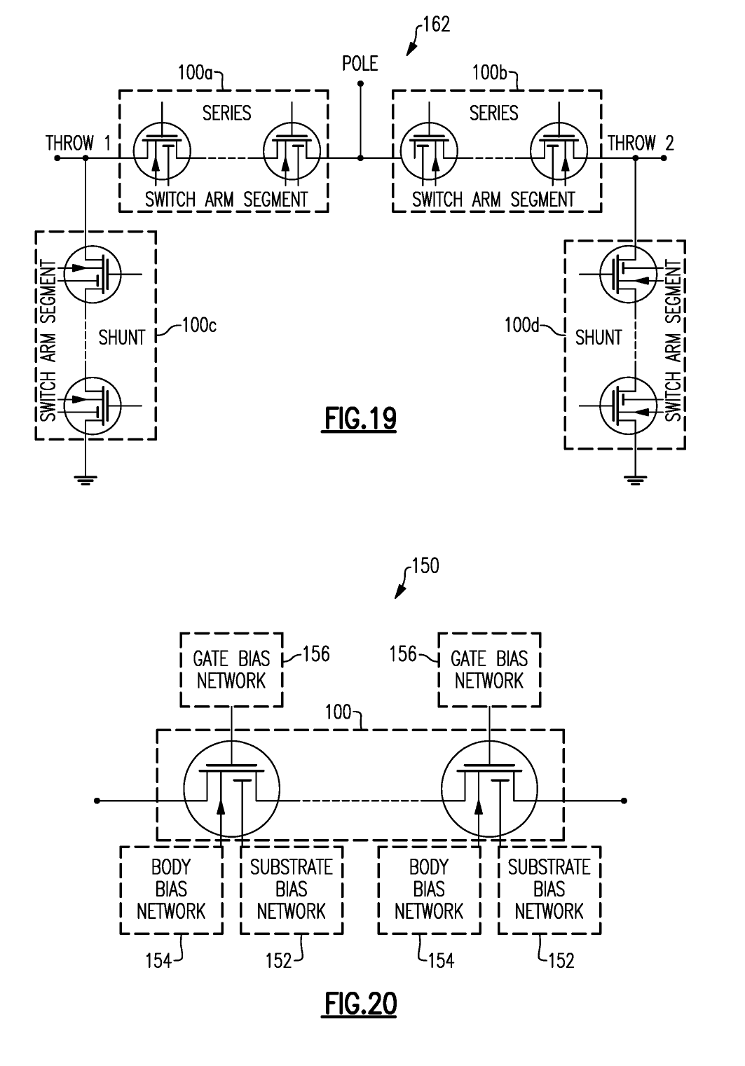

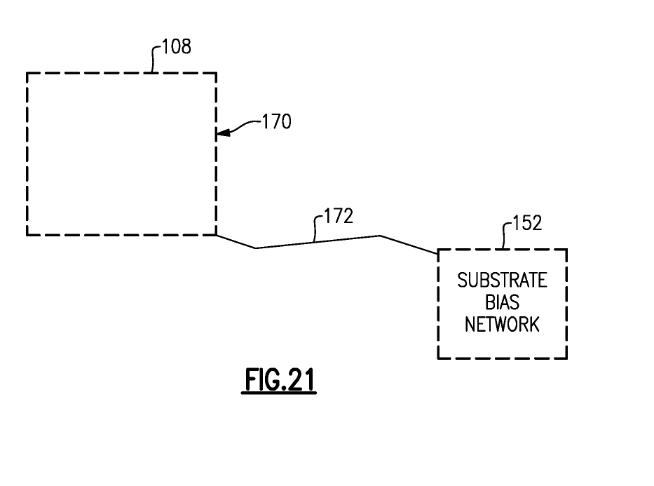

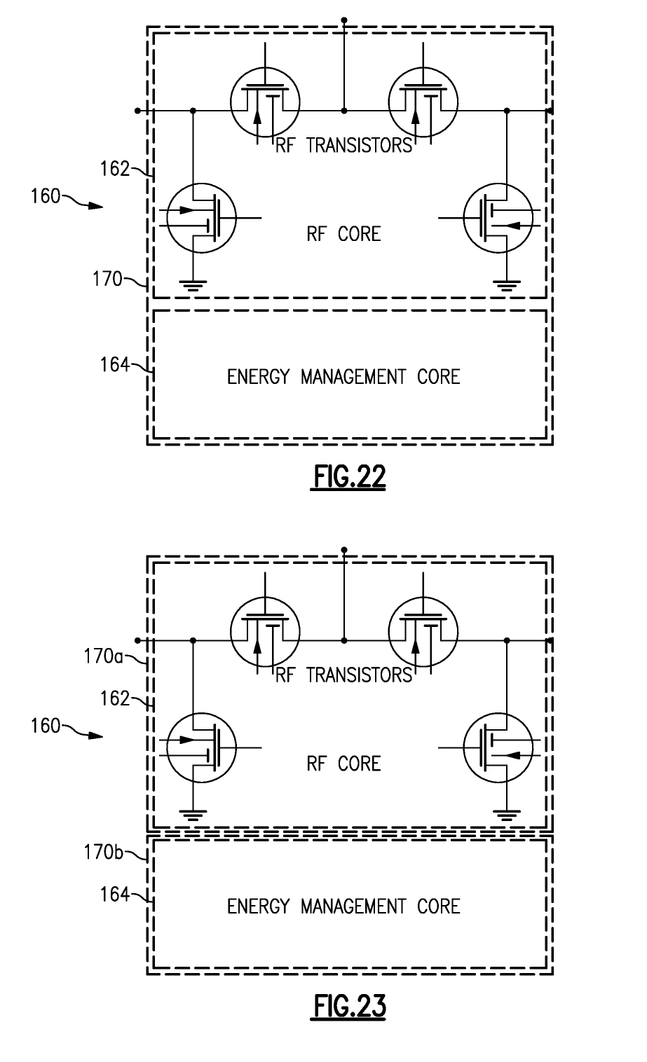

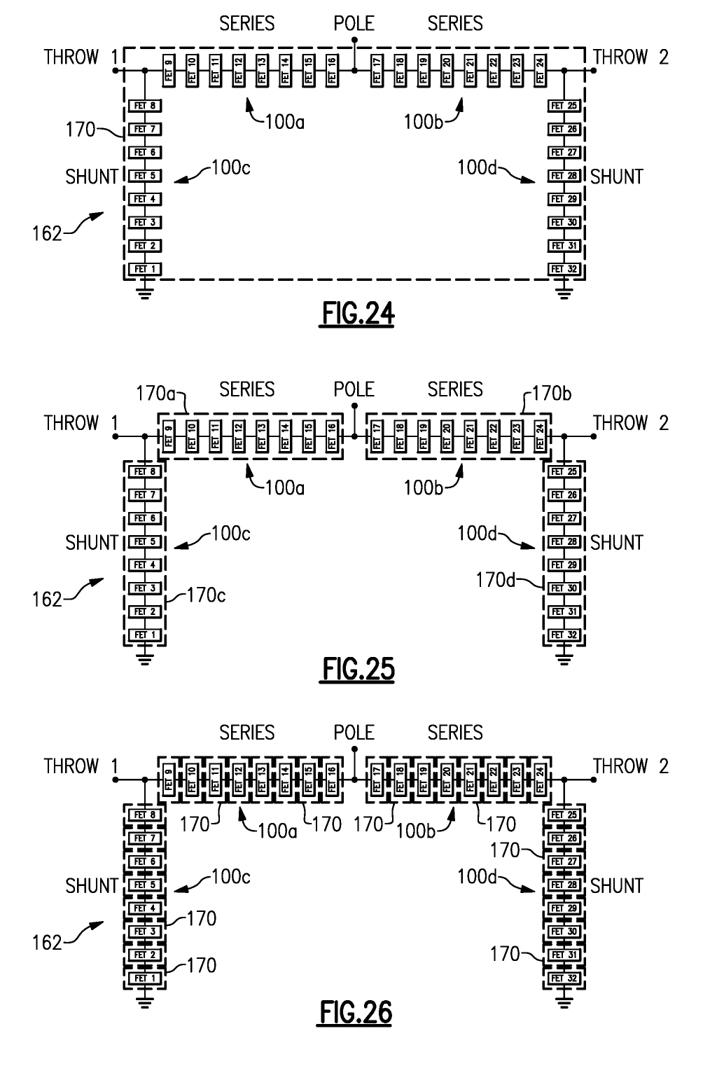

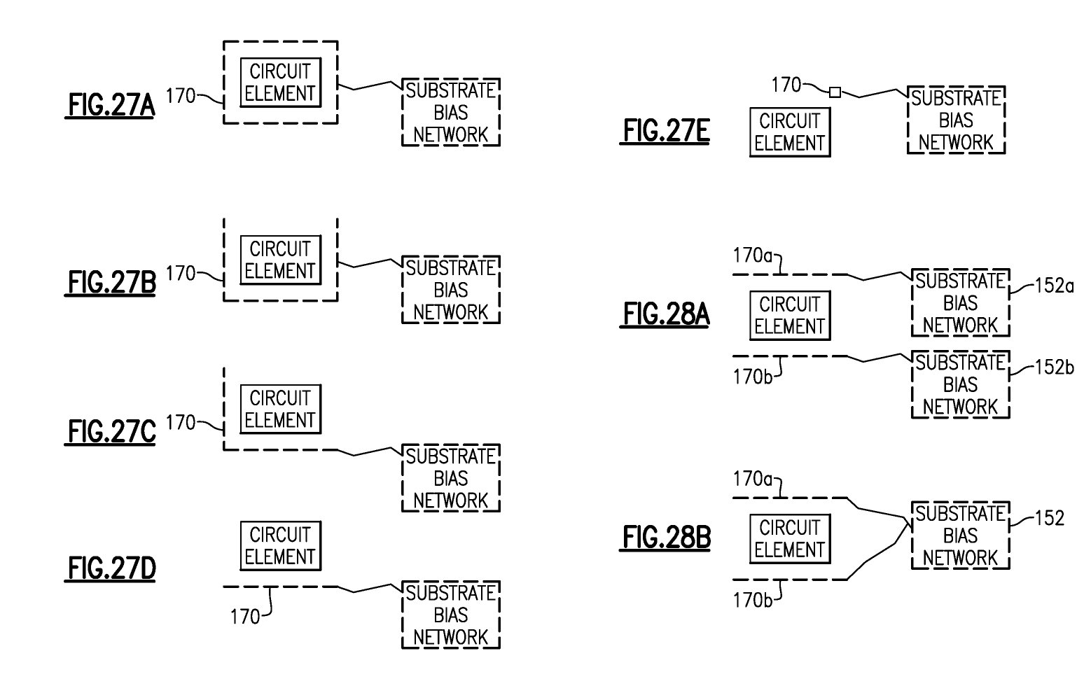

FIGS. 22-27 show non-limiting examples of the pattern 170 of one or more conductive features 108 of FIG. 21. In the examples of FIGS. 22-26, a pattern of such conductive feature(s) is depicted as generally surrounding a corresponding circuit element. However, and as shown in FIGS. 27A-27E, such a pattern of conductive feature(s) may or may not surround a corresponding circuit element.

In the examples of FIGS. 22-27, it will be understood that for some or all of such examples, the pattern of conductive feature(s) can be electrically connected to another node of the SOI FET device, with or without the substrate bias network 152. As described herein, such pattern of conductive feature(s) can include, for example, one or more conductive vias, one or more conductive trenches, or any combination thereof. Other types of conductive features can also be implemented.

FIG. 22 shows an example configuration 160 in which a pattern 170 of conductive features for substrate connection can generally form a ring shaped perimeter substantially around an entire die having an RF core 162 and an EM core 164. Accordingly, the RF core 162 and the EM core 164 collectively can be a circuit element associated with the pattern 170 of conductive features.

FIG. 23 shows an example configuration 160 in which a pattern of conductive features for substrate connection can generally form a ring shaped distribution implemented substantially around each of an RF core 162 (pattern 170a) and an EM core 164 (pattern 170b) of a switching die. Accordingly, the RF core 162 can be a circuit element associated with the pattern 170a of conductive features, and the EM core 164 can be a circuit element associated with the pattern 170b of conductive features. Although both of the RF and EM cores are depicted as having respective patterns of conductive features, it will be understood that one pattern can have such substrate connection while the other pattern does not. For example, the RF core can have such a substrate connection while the EM core does not.

FIGS. 24-26 show examples of one or more patterns of conductive features for substrate connection that can be implemented for an RF core 162. FIG. 24 shows an example configuration in which a pattern 170 of conductive features for substrate connection can generally form a ring shaped distribution implemented substantially around an assembly of series arms 100a, 100b and shunt arms 100c, 100d. Accordingly, the RF core 162 can be a circuit element associated with the pattern 170 of conductive features.

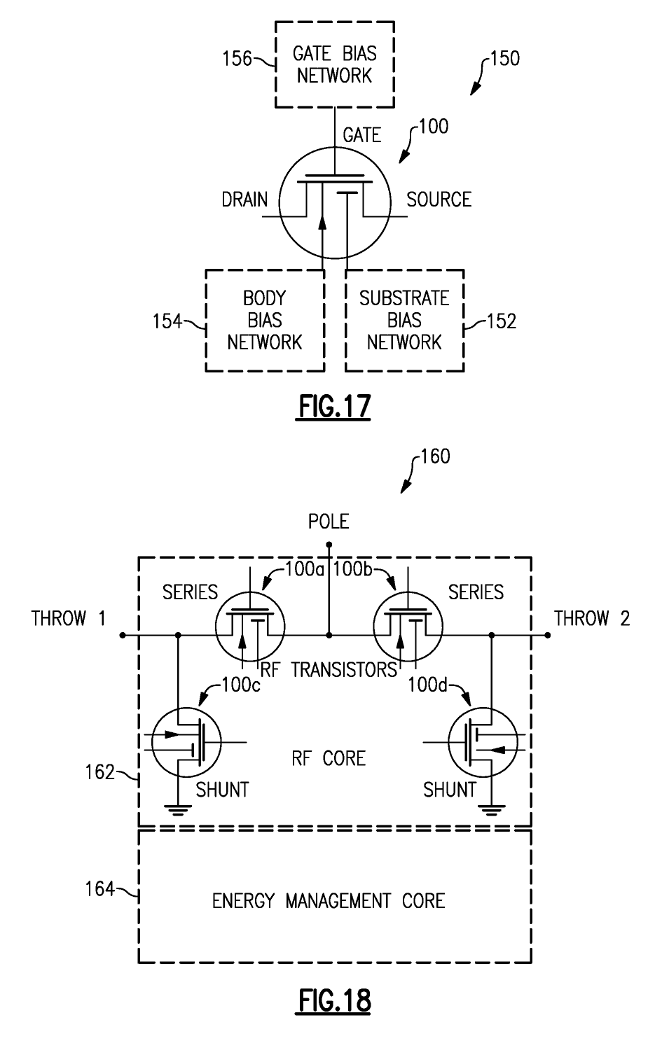

FIG. 25 shows an example configuration in which a pattern of conductive features for substrate connection can generally form a ring shaped distribution implemented substantially around each of series arms 100a (pattern 170a), 100b (pattern 170b) and shunt arms 100c (pattern 170c), 100d (pattern 170d). Accordingly, each arm (100a, 100b, 100c or 100d) can be a circuit element associated with the corresponding pattern (170a, 170b, 170c or 170d) of conductive features.

FIG. 26 shows an example configuration in which a pattern 170 of conductive features for substrate connection can generally form a ring shaped distribution implemented substantially around each FET in a given arm. Accordingly, each FET can be a circuit element associated with the corresponding pattern of conductive features.

In the examples of FIGS. 24-26, each component at different levels of the RF core is shown to be provided with a pattern of conductive features. For example, each arm in FIG. 25 is shown to include a pattern of conductive features, and each FET in FIG. 26 is shown to include a pattern of conductive features. It will be understood that not every one of such components necessarily needs to have such pattern of conductive features. Further, it will be understood that various combinations of the patterns of conductive features associated with different levels of the RF core can be combined. For example, an RF core can include a pattern of conductive features around the RF core itself, and one or more additional patterns of conductive features can also be implemented for selected arm(s) and/or FET(s).

As described herein, a pattern of conductive features for substrate connection can be implemented around a circuit element, partially around a circuit element, as a single feature, or any combination thereof.

FIGS. 27A-27E show non-limiting examples of such patterns. In such examples, the patterns are depicted as being electrically connected to their respective substrate bias networks. However, and as described herein, such patterns can be electrically connected to other part(s) of, for example, corresponding FET with or without such substrate bias networks.

FIG. 27A shows an example in which a pattern 170 of conductive features for substrate connection can be implemented around a circuit element, similar to the examples of FIGS. 22-26. Such a pattern can be electrically connected to a substrate bias network and/or another portion of the circuit element.

FIG. 27B shows an example in which a pattern 170 of conductive features for substrate connection can be implemented partially around a circuit element. In the particular example of FIG. 27B, such a partially surrounding pattern can be a U-shaped pattern in which conductive features are implemented on three sides, but not on the fourth side relative to the circuit element. Such a pattern can be electrically connected to a substrate bias network and/or another portion of the circuit element.

FIG. 27C shows another example in which a pattern 170 of conductive features for substrate connection can be implemented partially around a circuit element. In the particular example of FIG. 27C, such a partially surrounding pattern can be an L-shaped pattern in which conductive features are implemented on two adjacent sides, but not on the other two sides relative to the circuit element. Such a pattern can be electrically connected to a substrate bias network and/or another portion of the circuit element. In some embodiments, two sides having patterns of conductive features can be opposing sides.

FIG. 27D shows yet another example in which a pattern 170 of conductive features for substrate connection can be implemented partially around a circuit element. In the particular example of FIG. 27D, such a partially surrounding pattern can be a pattern in which conductive features are implemented on one side, but not on the remaining three sides relative to the circuit element. Such a pattern can be electrically connected to a substrate bias network and/or another portion of the circuit element.

FIG. 27E shows an example in which a pattern 170 of conductive features for substrate connection can be implemented as one or more discrete contact points. In the particular example of FIG. 27E, such a pattern can be a pattern in which a single conductive feature is implemented relative to the circuit element. Such a pattern can be electrically connected to a substrate bias network and/or another portion of the circuit element.

In the examples of FIGS. 27A-27E, a given pattern 170 can include one or more discrete and/or contiguous conductive features. For the purpose of description, it will be understood that a contiguous pattern (e.g., two joined segments in the example of FIG. 17C) can include conductive features that are electrically connected to a common substrate bias network and/or another common portion of the circuit element.

FIGS. 28A and 28B show that in some embodiments, there may be more than one pattern of conductive features implemented relative a circuit element. Such patterns of conductive features can be electrically connected to separate substrate bias networks and/or portions of the circuit element, be electrically connected to a common substrate bias network and/or another common portion of the circuit element, or any combination thereof.

For example, FIG. 28A shows a configuration in which two opposing sides relative to a circuit element are provided with first and second patterns 170a, 170b of conductive features. The first pattern 170a can be electrically connected to a first substrate bias network 152a and/or a first portion of the circuit element, and the second pattern 170b can be electrically connected to a second substrate bias network 152b and/or a second portion of the circuit element.

In another example, 28B shows a configuration in which two opposing sides relative to a circuit element are provided with first and second patterns 170a, 170b of conductive features, similar to the example of FIG. 28A. Both of the first and second patterns 170a, 170b can be electrically connected to a common substrate bias network 152 and/or a common portion of the circuit element.

FIGS. 29-46 show non-limiting examples of substrate bias networks and/or other portions of an SOI FET device 100 that can be coupled with a substrate node of the SOI FET device 100. Such coupling with the substrate node can be facilitate by one or more patterns of conductive features as described in reference to FIGS. 21-28.

FIG. 29 shows an example in which a substrate node of an SOI FET device 100 can be electrically connected to a substrate bias network 152. Such a substrate bias network can be configured to allow application of a DC control voltage (V_control) to the substrate node.

FIG. 30 shows an example in which a substrate node of an SOI FET device 100 can be electrically connected to a substrate bias network 152. Such a substrate bias network can be configured to allow application of a DC control voltage (V_control) to the substrate node through a resistance R (e.g., a resistor).

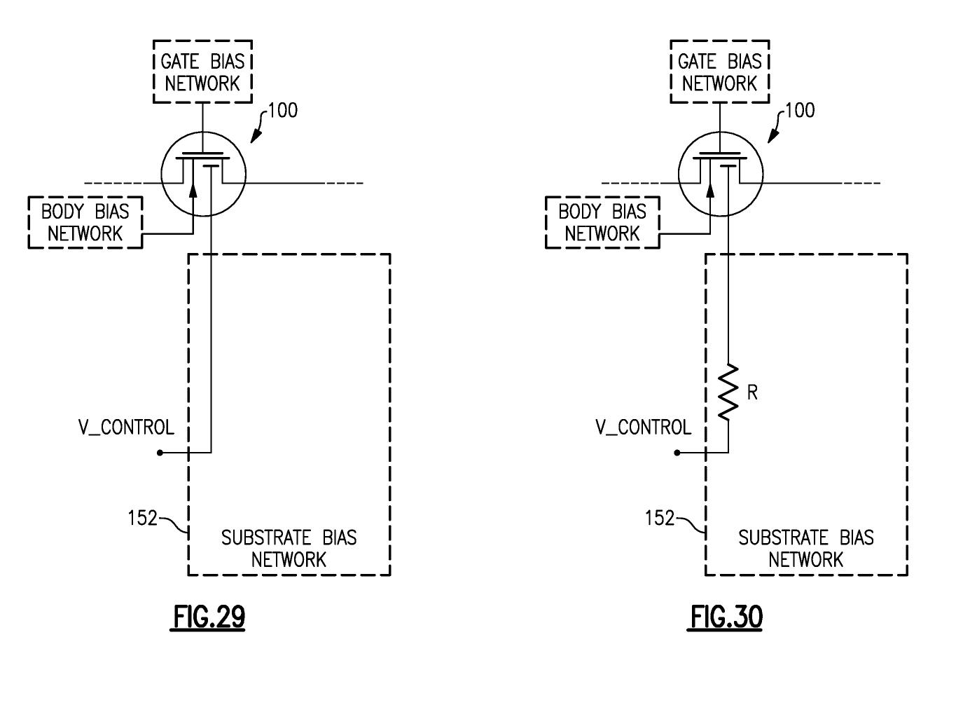

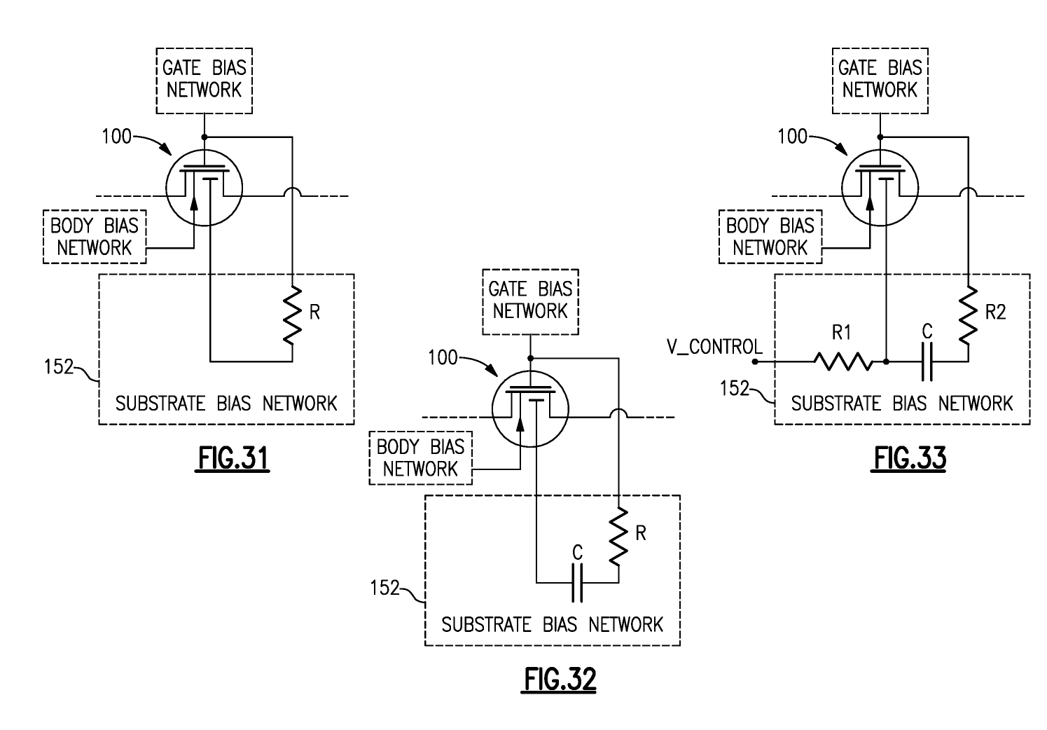

FIG. 31 shows an example in which a substrate node of an SOI FET device 100 can be electrically connected to a gate node (e.g., back-side of the gate) of the SOI FET device 100. In some embodiments, such a coupling may or may not include a resistance R (e.g., a resistor). In some embodiments, such a coupling may or may not be part of a substrate bias network 152 (if any).

FIG. 32 shows an example in which a substrate node of an SOI FET device 100 can be electrically connected to a gate node (e.g., back-side of the gate) of the SOI FET device 100 through a phase-shift circuit. In the example shown, the phase-shift circuit includes a capacitance (e.g., a capacitor); however, it will be understood that the phase-shift circuit can be configured in other manners. In some embodiments, such a coupling may or may not include a resistance R (e.g., a resistor). In some embodiments, such a coupling may or may not be part of a substrate bias network 152 (if any).

FIG. 33 shows an example in which a substrate node of an SOI FET device 100 can be electrically connected to a gate node (e.g., back-side of the gate) of the SOI FET device 100 through a phase-shift circuit, similar to the example of FIG. 32. In the example of FIG. 33, a substrate bias network 152 can be configured to allow application of a DC control voltage (V_control) to the substrate node. Such V_control can be applied directed to the substrate node, or through a resistance R1 (e.g., a resistor).

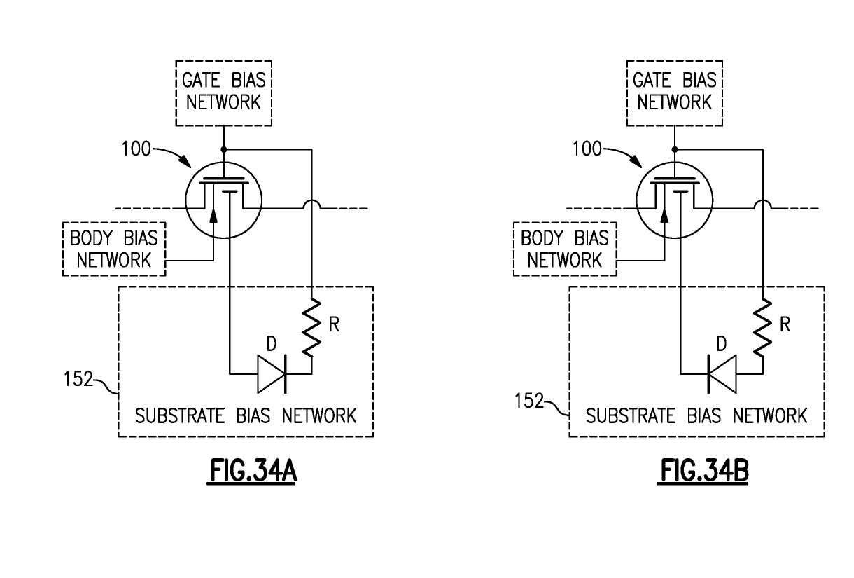

FIGS. 34-37 show non-limiting examples in which various couplings between a substrate node of an SOI FET device and another node of the SOI FET device can include a diode. Such a diode can be implemented to, for example, provide voltage-dependent couplings.

FIG. 34A shows an example that is similar to the example of FIG. 31, but with a diode D in series with the resistance R. In some embodiments, such a coupling between the substrate node the gate node can be implemented with or without the resistance R.

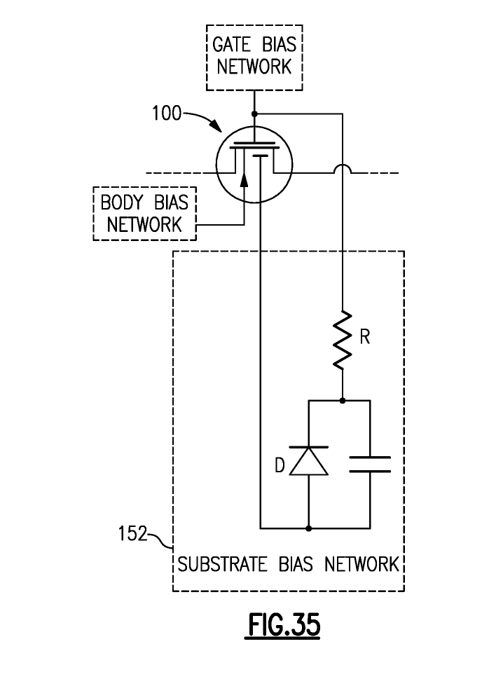

FIG. 34B shows that in some embodiments, the polarity of the diode D can be reversed from the example of FIG. 34A. It will be understood that such polarity reversal of the diode can also be implemented in the examples of FIGS. 35-37.

FIG. 35 shows an example that is similar to the example of FIG. 32, but with a diode D in parallel with a phase-shifting circuit (e.g., a capacitance C). In some embodiments, such a coupling between the substrate node the gate node can be implemented with or without the resistance R.

FIG. 36 shows an example that is similar to the example of FIG. 31, but with a diode D in series with the resistance R. In some embodiments, a DC control voltage (V_control) can be applied directly to the substrate node, or through a resistance (e.g., a resistor).

FIG. 37 shows an example that is similar to the example of FIG. 35, but with biasing. Such biasing can be configured to allow application of a DC control voltage (V_control) to the substrate node directly or through a resistance R (e.g., a resistor).

In some embodiments, a substrate node connection having one or more features as described herein can be utilized to sense a voltage condition of the substrate. Such a sensed voltage can be utilized to, for example, compensate the voltage condition. For example, charge can be driven into or out of the substrate as needed or desired through the substrate node connection.

FIG. 38 shows an SOI FET device 100 having a substrate connection as described herein. Such a substrate connection can be utilized to sense a voltage V associated with the substrate node. FIGS. 39-46 show non-limiting examples of how such sensed voltage can be utilized in various feedback and/or biasing configurations. Although various examples are described in the context of voltage V, it will be understood that one or more features of the present disclosure can also be implemented utilizing, for example, sensed current associated with the substrate.

FIGS. 39A-39D show examples of how a substrate node of an SOI FET device 100 can be coupled to another node of the SOI FET device 100. In some embodiments, such couplings can be utilized to facilitate the foregoing compensation based on the sensed substrate voltage of FIG. 38. FIG. 39A shows that a coupling 190 can be implemented between the substrate node and a gate node. FIG. 39B shows that a coupling 190 can be implemented between the substrate node and a body node. FIG. 39C shows that a coupling 190 can be implemented between the substrate node and a source node. FIG. 39D shows that a coupling 190 can be implemented between the substrate node and a drain node. In some embodiments, the substrate node can be coupled to more than one of the foregoing nodes.

FIGS. 40A-40D show examples of how a substrate node of an SOI FET device 100 can be coupled to another node of the SOI FET device 100 through a phase-shifting circuit (e.g., a capacitance) 192. In some embodiments, such couplings can be utilized to facilitate the foregoing compensation based on the sensed substrate voltage of FIG. 38. FIG. 40A shows that a coupling 190 having a phase-shifting circuit 192 can be implemented between the substrate node and a gate node. FIG. 40B shows that a coupling 190 having a phase-shifting circuit 192 can be implemented between the substrate node and a body node. FIG. 40C shows that a coupling 190 having a phase-shifting circuit 192 can be implemented between the substrate node and a source node. FIG. 40D shows that a coupling 190 having a phase-shifting circuit 192 can be implemented between the substrate node and a drain node. In some embodiments, the substrate node can be coupled to more than one of the foregoing nodes.

FIGS. 41A-41D show examples that are similar to the examples of FIGS. 39A-39D. However, in each of the examples of FIGS. 41A-41D, a bias signal such as a DC control voltage (V_control) can be applied to the substrate node. Such V_control can be applied to the substrate node directly or through a resistance.

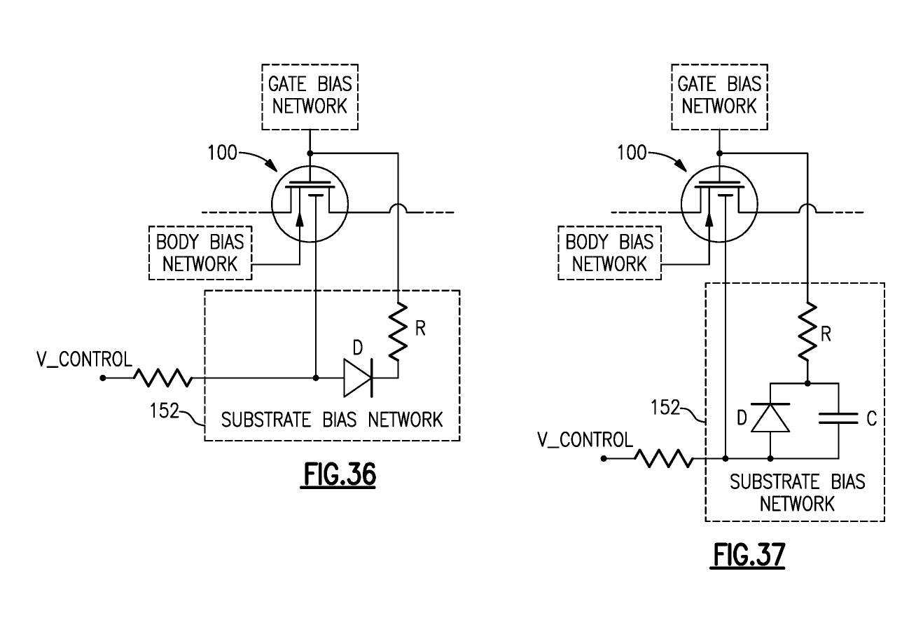

FIGS. 42A-42D show examples that are similar to the examples of FIGS. 40A-40D. However, in each of the examples of FIGS. 42A-42D, a bias signal such as a DC control voltage (V_control) can be applied to the substrate node. Such V_control can be applied to the substrate node directly or through a resistance.

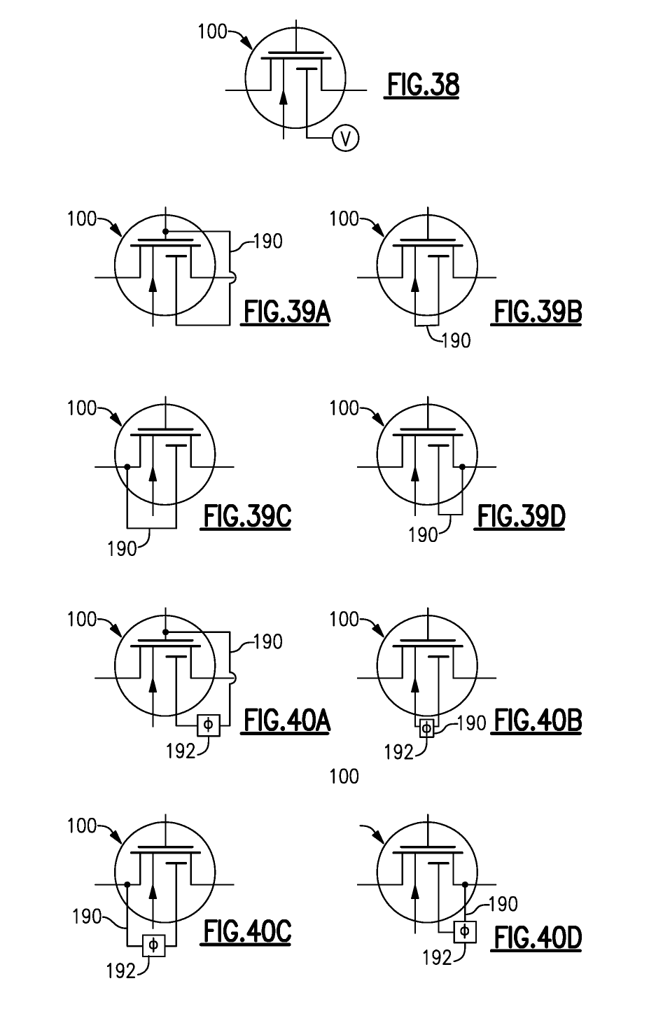

FIGS. 43A-43D show examples of how a substrate node of an SOI FET device 100 can be coupled to another node of the SOI FET device 100 through a diode D. In some embodiments, such couplings can be utilized to facilitate the foregoing compensation based on the sensed substrate voltage of FIG. 38. In some embodiments, a given diode can be reversed from the configuration as shown as needed or desired.

FIG. 43A shows that a coupling 190 having a diode D can be implemented between the substrate node and a gate node. FIG. 43B shows that a coupling 190 having a diode D can be implemented between the substrate node and a body node. FIG. 43C shows that a coupling 190 having a diode D can be implemented between the substrate node and a source node. FIG. 43D shows that a coupling 190 having a diode D can be implemented between the substrate node and a drain node. In some embodiments, the substrate node can be coupled to more than one of the foregoing nodes.

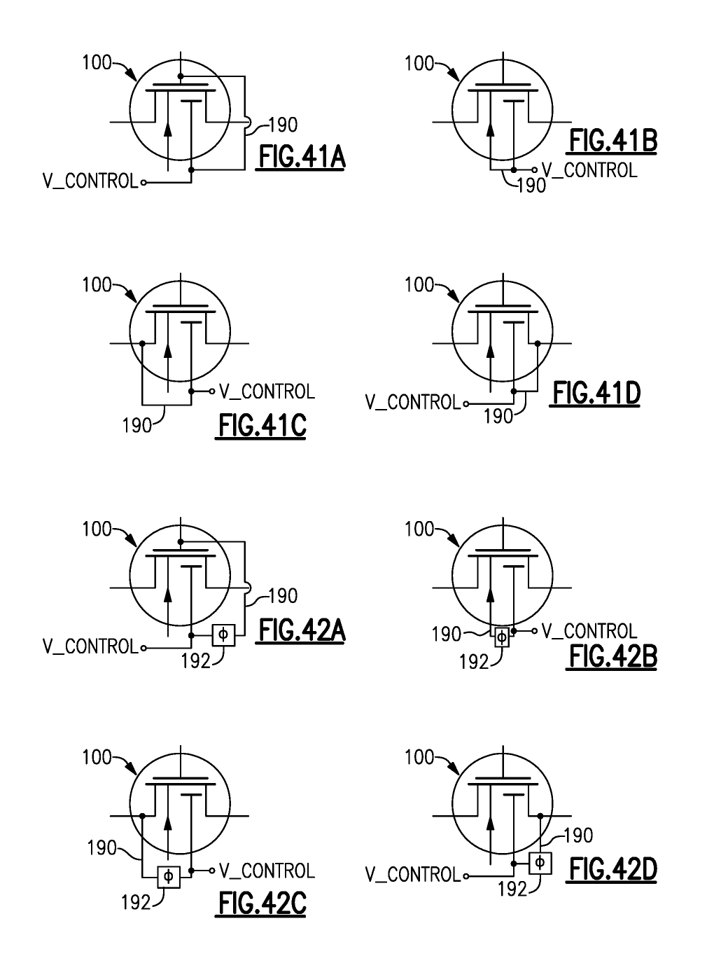

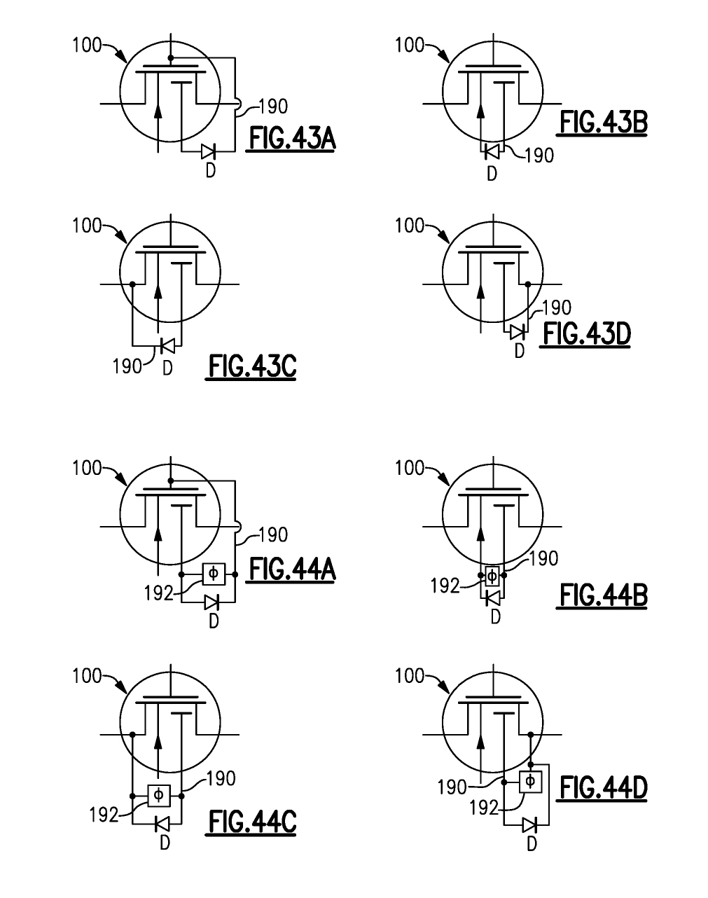

FIGS. 44A-44D show examples of how a substrate node of an SOI FET device 100 can be coupled to another node of the SOI FET device 100 through a diode D and a phase-shifting circuit 192. In some embodiments, such diode D and the phase-shifting circuit 192 can be arranged in a parallel configuration. In some embodiments, such couplings can be utilized to facilitate the foregoing compensation based on the sensed substrate voltage of FIG. 38. In some embodiments, a given diode can be reversed from the configuration as shown as needed or desired.

FIG. 44A shows that a coupling 190 having a diode D and a phase-shifting circuit 190 can be implemented between the substrate node and a gate node. FIG. 44B shows that a coupling 190 having a diode D and a phase-shifting circuit 190 can be implemented between the substrate node and a body node. FIG. 44C shows that a coupling 190 having a diode D and a phase-shifting circuit 190 can be implemented between the substrate node and a source node. FIG. 44D shows that a coupling 190 having a diode D and a phase-shifting circuit 190 can be implemented between the substrate node and a drain node. In some embodiments, the substrate node can be coupled to more than one of the foregoing nodes.

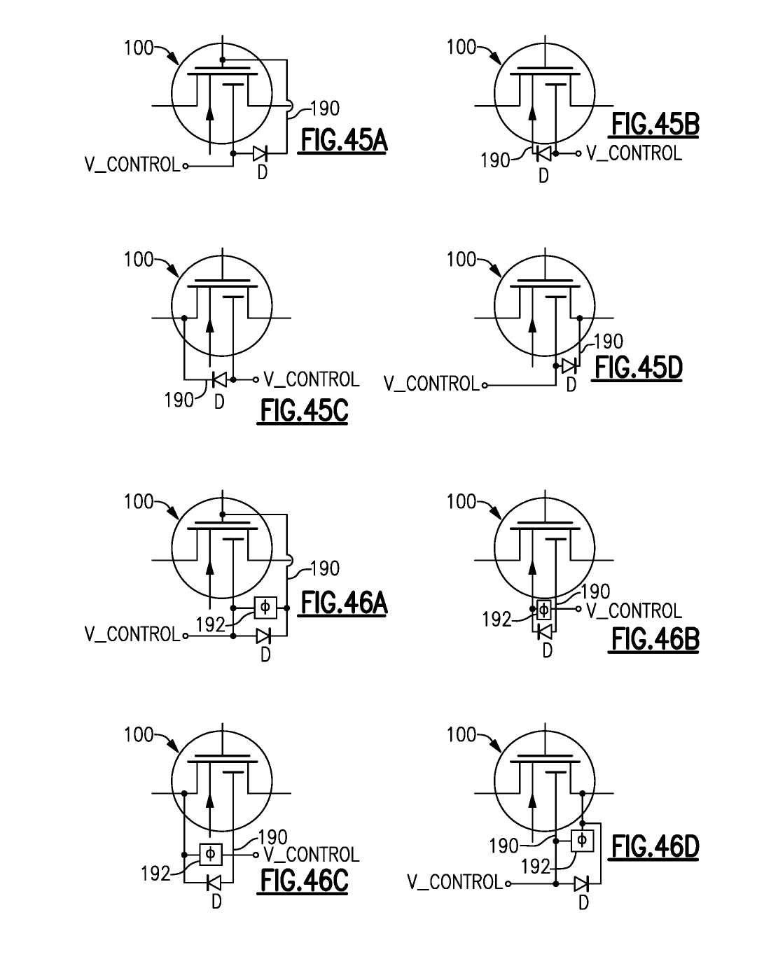

FIGS. 45A-45D show examples that are similar to the examples of FIGS. 43A-43D. However, in each of the examples of FIGS. 45A-45D, a bias signal such as a DC control voltage (V_control) can be applied to the substrate node. Such V_control can be applied to the substrate node directly or through a resistance.

FIGS. 46A-46D show examples that are similar to the examples of FIGS. 44A-44D. However, in each of the examples of FIGS. 46A-46D, a bias signal such as a DC control voltage (V_control) can be applied to the substrate node. Such V_control can be applied to the substrate node directly or through a resistance.

### Examples Related to Switch Configurations

As described herein in reference to the examples of FIGS. 18, 19 and 22-26, FET devices having one or more features of the present disclosure can be utilized to implement an SPDT switch configuration. It will be understood that FET devices having one or more features of the present disclosure can also be implemented in other switch configurations.

FIGS. 47-57 show examples related to various switch configurations that can be implemented utilizing FET devices such as SOI FET devices having one or more features as described herein. For example, FIG. 47 shows a switch assembly 250 implemented in a single-pole-single-throw (SPST) configuration. Such a switch can include an SOI FET device 100 implemented between a first port (Port1) and a second port (Port2).

FIG. 48 shows that in some embodiments, the SOI FET device 100 of FIG. 47 can include a substrate biasing/coupling feature as described herein. The source node of the SOI FET device 100 can be connected to the first port (Port1), and the drain node of the SOI FET device 100 can be connected to the second port (Port2). As described herein, the SOI FET device 100 can be turned ON to close the switch 250 (of FIG. 47) between the two ports, and turned OFF to open the switch 250 between the two ports.

It will be understood that the SOI FET device 100 of FIGS. 47 and 48 can include a single FET, or a plurality of FETs arranged in a stack. It will also be understood that each of various SOI FET devices 100 of FIGS. 49-57 can include a single FET, or a plurality of FETs arranged in a stack.

FIG. 49 shows an example of how two SPST switches (e.g., similar to the examples of FIGS. 47, 48) having one or more features as described herein can be utilized to form a switch assembly 250 having a single-pole-double-throw (SPDT) configuration. FIG. 50 shows, in a SPDT representation, that the switch assembly 250 of FIG. 49 can be utilized in an antenna switch configuration 260. It will be understood that one or more features of the present disclosure can also be utilized in switching applications other than antenna switching application.

It is noted that in various switching configuration examples of FIGS. 47-57, switchable shunt paths are not shown for simplified views of the switching configurations. Accordingly, it will be understood that some or all of switchable paths in such switching configurations may or may not have associated with them switchable shunt paths (e.g., similar to the examples of FIGS. 18, 19 and 22-26).

Referring to the examples of FIGS. 49 and 50, it is noted that such examples are similar to the examples described herein in reference to FIGS. 18, 19 and 22-26. In some embodiments, the single pole (P) of the switch assembly 250 of FIG. 49 can be utilized as an antenna node (Ant) of the antenna switch 260, and the first and second throws (T1, T2) of the switch assembly 250 of FIG. 49 can be utilized as TRx1 and TRx2 nodes, respectively, of the antenna switch 260. Although each of the TRx1 and TRx2 nodes is indicated as providing transmit (Tx) and receive (Rx) functionalities, it will be understood that each of such nodes can be configured to provide either or both of such Tx and Rx functionalities.

In the examples of FIGS. 49 and 50, the SPDT functionality is shown to be provided by two SPST switches 100a, 100b, with the first SPST switch 100a providing a first switchable path between the pole P (Ant in FIG. 50) and the first throw T1 (TRx1 in FIG. 50), and the second SPST switch 100b providing a second switchable path between the pole P (Ant in FIG. 50) and the second throw T2 (TRx2 in FIG. 50). Accordingly, selective coupling of the pole (Ant) with either of the first throw T1 (TRx1) and the second throw T2 (TRx2) can be achieved by selective switching operations of the first and second SPST switches. For example, if a connection is desired between the pole (Ant) and the first throw T1 (TRx1), the first SPST switch 100a can be closed, and the second SPST switch 100b can be opened. Similarly, and as depicted in the example state in FIGS. 49 and 50, if a connection is desired between the pole (Ant) and the second throw T2 (TRx2), the first SPST switch 100a can be opened, and the second SPST switch 100b can be closed.

In the foregoing switching examples of FIGS. 49 and 50, a single TRx path is connected to the antenna (Ant) node in a given switch configuration. It will be understood that in some applications (e.g., carrier-aggregation applications), more than one TRx paths may be connected to the same antenna node. Thus, in the context of the foregoing switching configuration involving a plurality of SPST switches, more than one of such SPST switches can be closed to thereby connect their respective throws (TRx nodes) to the same pole (Ant).

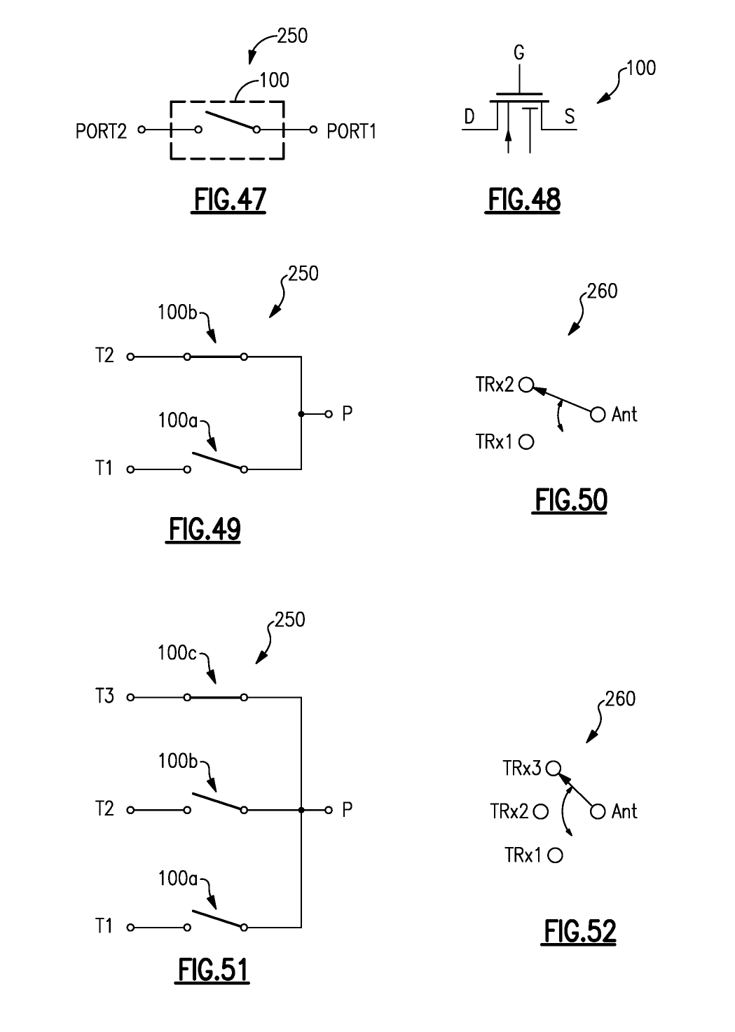

FIG. 51 shows an example of how three SPST switches (e.g., similar to the examples of FIGS. 47, 48) having one or more features as described herein can be utilized to form a switch assembly 250 having a single-pole-triple-throw (SP3T) configuration. FIG. 52 shows, in a SP3T representation, that the switch assembly 250 of FIG. 51 can be utilized in an antenna switch configuration 260. It will be understood that one or more features of the present disclosure can also be utilized in switching applications other than antenna switching application.

Referring to the examples of FIGS. 51 and 52, it is noted that the SP3T configuration can be an extension of the SPDT configuration of FIGS. 49 and 50. For example, the single pole (P) of the switch assembly 250 of FIG. 51 can be utilized as an antenna node (Ant) of the antenna switch 260, and the first, second and third throws (T1, T2, T3) of the switch assembly 250 of FIG. 51 can be utilized as TRx1, TRx2 and TRx3 nodes, respectively, of the antenna switch 260. Although each of the TRx1, TRx2 and TRx3 nodes is indicated as providing transmit (Tx) and receive (Rx) functionalities, it will be understood that each of such nodes can be configured to provide either or both of such Tx and Rx functionalities.

In the examples of FIGS. 51 and 52, the SP3T functionality is shown to be provided by three SPST switches 100a, 100b, 100c, with the first SPST switch 100a providing a first switchable path between the pole P (Ant in FIG. 52) and the first throw T1 (TRx1 in FIG. 52), the second SPST switch 100b providing a second switchable path between the pole P (Ant in FIG. 52) and the second throw T2 (TRx2 in FIG. 52), and the third SPST switch 100c providing a third switchable path between the pole P (Ant in FIG. 52) and the third throw T3 (TRx3 in FIG. 52). Accordingly, selective coupling of the pole (Ant) with one of the first throw T1 (TRx1), the second throw T2 (TRx2), and the third throw T3 (TRx3) can be achieved by selective switching operations of the first, second and third SPST switches. For example, if a connection is desired between the pole (Ant) and the first throw T1 (TRx1), the first SPST switch 100a can be closed, and each of the second and third SPST switches 100b, 100c can be opened. If a connection is desired between the pole (Ant) and the second throw T2 (TRx2), the second SPST switch 100b can be closed, and each of the first and third SPST switches 100a, 100c can be opened. Similarly, and as depicted in the example state in FIGS. 51 and 52, if a connection is desired between the pole (Ant) and the third throw T3 (TRx3), each of the first and second SPST switches 100a, 100b can be opened, and the third SPST switch 100c can be closed.

In the foregoing switching examples of FIGS. 51 and 52, a single TRx path is connected to the antenna (Ant) node in a given switch configuration. It will be understood that in some applications (e.g., carrier-aggregation applications), more than one TRx paths may be connected to the same antenna node. Thus, in the context of the foregoing switching configuration involving a plurality of SPST switches, more than one of such SPST switches can be closed to thereby connect their respective throws (TRx nodes) to the same pole (Ant).

Based on the foregoing examples of SPST, SPDT and SP3T configurations of FIGS. 47-52, one can see that other switching configurations involving a single pole (SP) can be implemented utilizing SOI FET devices having one or more features as described herein. Thus, it will be understood that a switch having a SPNT can be implemented utilizing one or more SOI FET devices as described herein, where the quantity N is a positive integer.

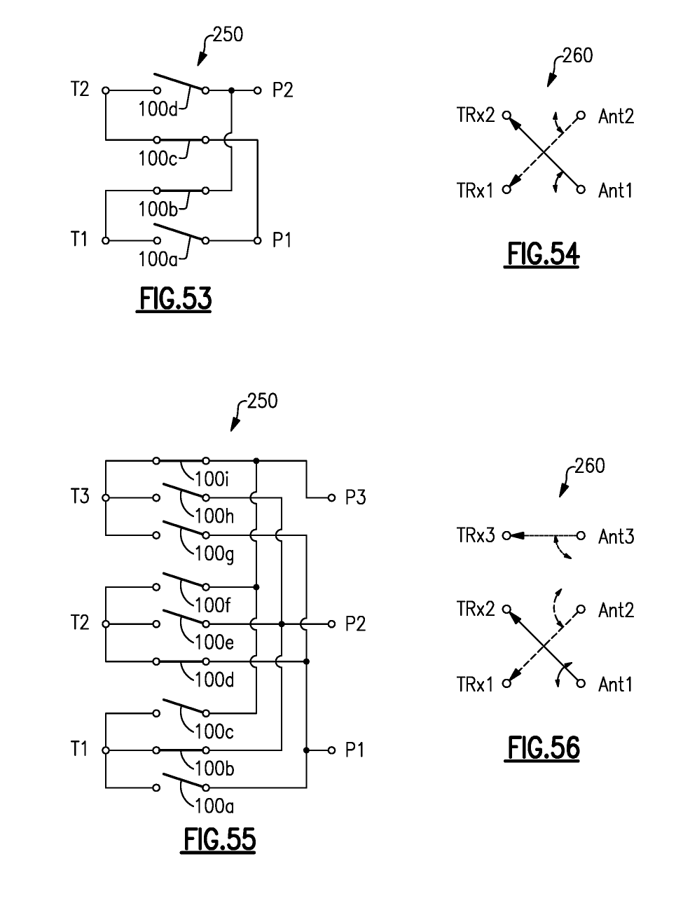

Switching configurations of FIGS. 49-52 are examples where a single pole (SP) is connectable to one or more of a plurality of throws to provide the foregoing SPNT functionality. FIGS. 53-56 show examples where more than one poles can be provided in switching configurations. FIGS. 53 and 54 show examples related to a double-pole-double-throw (DPDT) switching configuration that can utilize a plurality of SOI FET devices having one or more features as described herein. Similarly, FIGS. 55 and 56 show examples related to a triple-pole-triple-throw (3P3T) switching configuration that can utilize a plurality of SOI FET devices having one or more features as described herein.

It will be understood that a switching configuration utilizing a plurality of SOI FET devices having one or more features as described herein can include more than three poles. Further, it is noted that in the examples of FIGS. 53-56, the number of throws (e.g., 2 in FIGS. 53 and 54, and 3 in FIGS. 55 and 56) are depicted as being the same as the corresponding number of poles for convenience. However, it will be understood that the number of throws may be different than the number of poles.

FIG. 53 shows an example of how four SPST switches (e.g., similar to the examples of FIGS. 47, 48) having one or more features as described herein can be utilized to form a switch assembly 250 having a DPDT configuration. FIG. 54 shows, in a DPDT representation, that the switch assembly 250 of FIG. 53 can be utilized in an antenna switch configuration 260. It will be understood that one or more features of the present disclosure can also be utilized in switching applications other than antenna switching application.

In the examples of FIGS. 53 and 54, the DPDT functionality is shown to be provided by four SPST switches 100a, 100b, 100c, 100d. The first SPST switch 100a is shown to provide a switchable path between a first pole P1 (Ant1 in FIG. 54) and a first throw T1 (TRx1 in FIG. 54), the second SPST switch 100b is shown to provide a switchable path between a second pole P2 (Ant2 in FIG. 54) and the first throw T1 (TRx1 in FIG. 54), the third SPST switch 100c is shown to provide a switchable path between the first pole P1 (Ant1 in FIG. 54) and a second throw T2 (TRx2 in FIG. 54), and the fourth SPST switch 100d is shown to provide a switchable path between the second pole P2 (Ant2 in FIG. 54) and the second throw T2 (TRx2 in FIG. 54). Accordingly, selective coupling between one or more of the poles (antenna nodes) with one or more of the throws (TRx nodes) can be achieved by selective switching operations of the four SPST switches 100a, 100b, 100c, 100d. Examples of such switching operations are described herein in greater detail.

FIG. 55 shows an example of how nine SPST switches (e.g., similar to the examples of FIGS. 47, 48) having one or more features as described herein can be utilized to form a switch assembly 250 having a 3P3T configuration. FIG. 56 shows, in a 3P3T representation, that the switch assembly 250 of FIG. 55 can be utilized in an antenna switch configuration 260. It will be understood that one or more features of the present disclosure can also be utilized in switching applications other than antenna switching application.

Referring to the examples of FIGS. 55 and 56, it is noted that the 3P3T configuration can be an extension of the DPDT configuration of FIGS. 53 and 54. For example, a third pole (P3) can be utilized as a third antenna node (Ant3), and a third throw (T3) can be utilized as a third TRx node (TRx3). Connectivity associated with such third pole and third throw can be implemented similar to the examples of FIGS. 53 and 54.

In the examples of FIGS. 55 and 56, the 3P3T functionality is shown to be provided by nine SPST switches 100a-100i. Such nine SPST switches can provide switchable paths as listed in Table 1.

TABLE 1

| SPST switch | Pole | Throw |
|---|---|---|
| 100a | P1 | T1 |
| 100b | P2 | T1 |
| 100c | P3 | T1 |
| 100d | P1 | T2 |
| 100e | P2 | T2 |
| 100f | P3 | T2 |
| 100g | P1 | T3 |
| 100h | P2 | T3 |
| 100i | P3 | T3 |

Based on the example of FIGS. 55 and 56, and Table 1, one can see that selective coupling between one or more of the poles (antenna nodes) with one or more of the throws (TRx nodes) can be achieved by selective switching operations of the nine SPST switches 100a-100i.

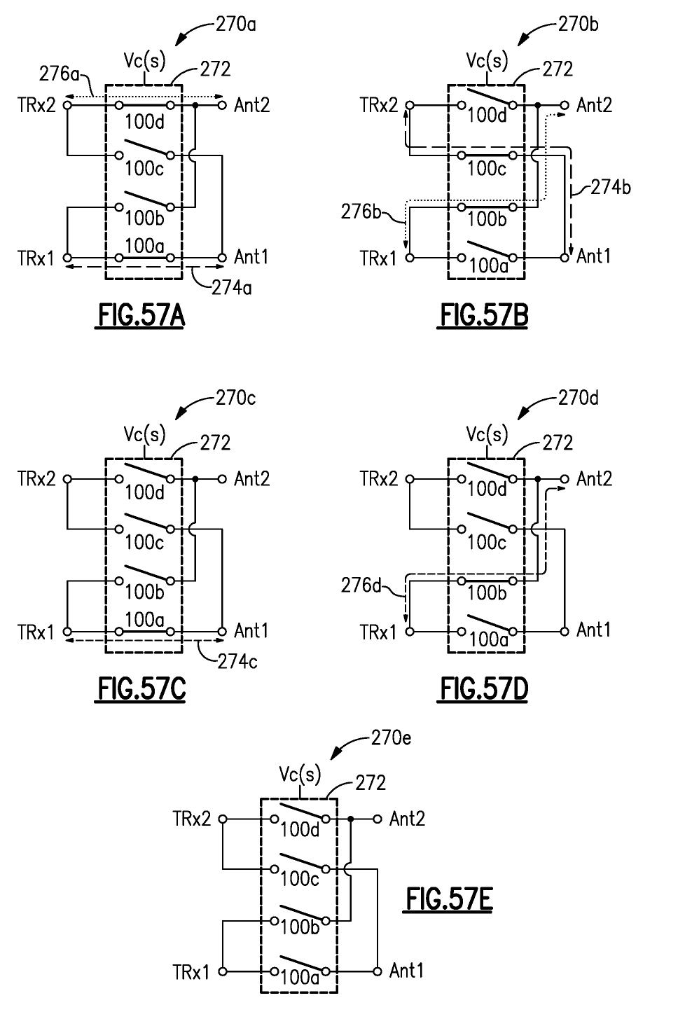

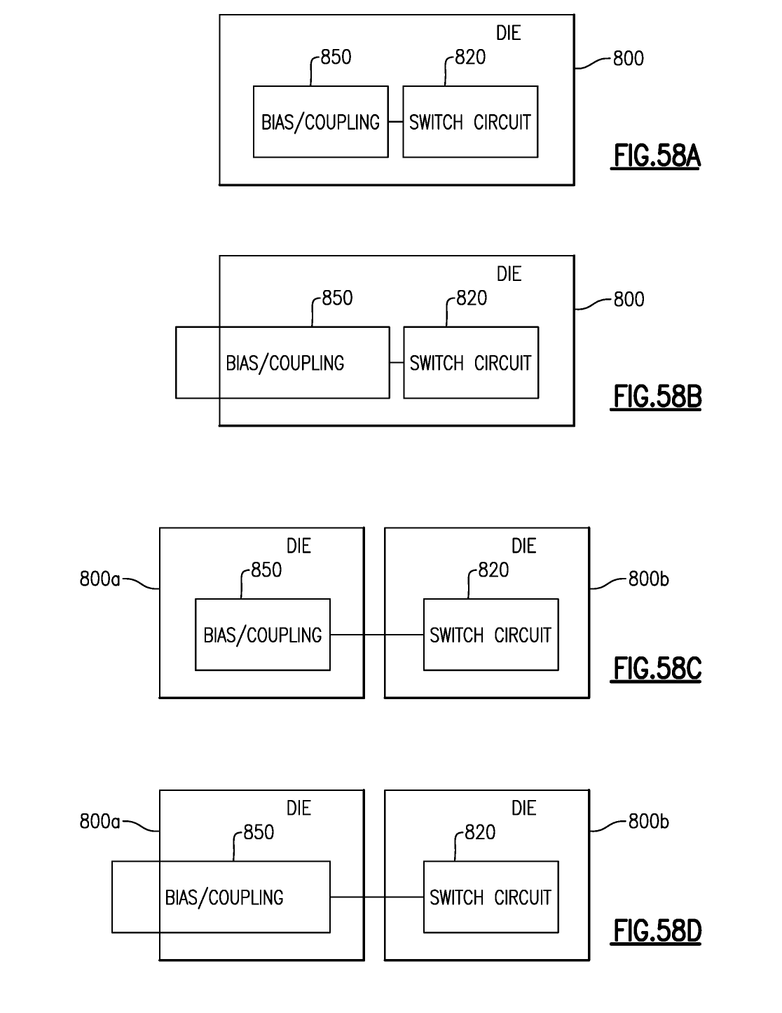

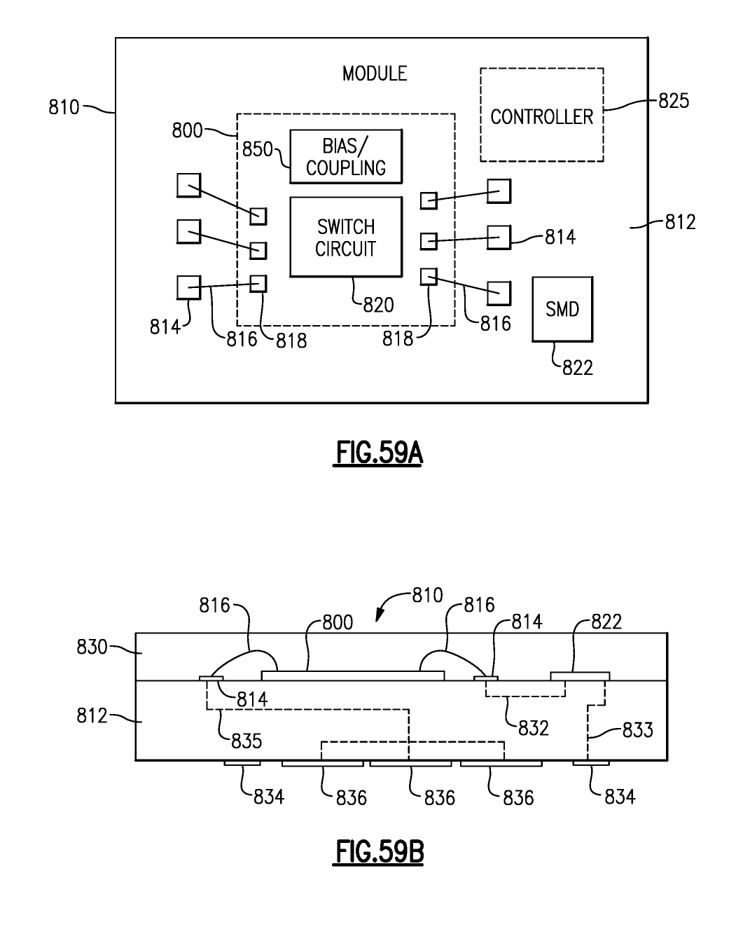

In many applications, switching configurations having a plurality of poles and a plurality of throws can provide increased flexibility in how RF signals can be routed therethrough. FIGS. 57A-57E show examples of how a DPDT switching configuration such as the examples of FIGS. 53 and 54 can be operated to provide different signal routing functionalities. It will be understood that similar control schemes can also be implemented for other switching configurations, such as the 3P3T examples of FIGS. 55 and 56.

In some wireless front-end architectures, two antennas can be provided, and such antennas can operate with two channels, with each channel being configured for either or both of Tx and Rx operations. For the purpose of description, it will be assumed that each channel is configured for both Tx and Rx operations (TRx). However, it will be understood that each channel does not necessarily need to have such TRx functionality. For example, one channel can be configured for TRx operations, while the other channel can be configured for Rx operation. Other configurations are also possible.

In the foregoing front-end architectures, there may be relatively simple switching states including a first state and a second state. In the first state, the first TRx channel (associated with the node TRx1) can operate with the first antenna (associated with the node Ant1), and the second TRx channel (associated with the node TRx2) can operate with the second antenna (associated with the node Ant2). In the second state, connections between the antenna nodes and the TRx nodes can be swapped from the first state. Accordingly, the first TRx channel (associated with the node TRx1) can operate with the second antenna (associated with the node Ant2), and the second TRx channel (associated with the node TRx2) can operate with the first antenna (associated with the node Ant1).

In some embodiments, such two states of the DPDT switching configuration can be controlled by a one-bit logic scheme, as shown in the example logic states in Table 2.

TABLE 2

| | | TRx1- | TRx1- | TRx2- | TRx2- |
|---|---|---|---|---|---|
| | Control | Ant1 | Ant2 | Ant1 | Ant2 |
| State | logic | connection | connection | connection | connection |
| 1 | 0 | Yes | No | No | Yes |
| 2 | 1 | No | Yes | Yes | No |

The first state (State 1) of the example of Table 2 is depicted in FIG. 57A as 270a, where the TRx1-Ant1 connection is indicated as path 274a, and the TRx2-Ant2 connection is indicated as path 276a. A control signal, representative of the control logic of Table 2, provided to the assembly (272) of the four SPST switches (100a, 100b, 100c, 100d) is collectively indicated as Vc(s). Similarly, the second state (State 2) of the example of Table 2 is depicted in FIG. 57B as 270b, where the TRx1-Ant2 connection is indicated as path 276b, and the TRx2-Ant1 connection is indicated as path 274b.

In some front-end architectures having a DPDT switching configuration, it may be desirable to have additional switching states. For example, it may be desirable to have only one path active among the two TRx channels and the two antennas. In another example, it may be desirable to disable all signal paths through the DPDT switch. Examples of 3-bit control logic that can be utilized to achieve such examples switching states are listed in Table 3.

TABLE 3

| | | TRx1- | TRx1- | TRx2- | TRx2- |
|---|---|---|---|---|---|
| | Control logic | Ant1 | Ant2 | Ant1 | Ant2 |
| State | (Vc1, Vc2, Vc3) | connection | connection | connection | connection |
| 1 | 0, 0, 0 | No | No | No | No |
| 2 | 0, 0, 1 | Yes | No | No | Yes |
| 3 | 0, 1, 0 | Yes | No | No | No |
| 4 | 0, 1, 1 | No | Yes | Yes | No |
| 5 | 1, 0, 0 | No | Yes | No | No |

The first state (State 1) of the example of Table 3 is depicted in FIG. 57E as 270e, where all of the TRx-Ant paths are disconnected. A control signal indicated as Vc(s) in FIG. 57E and as listed in Table 3 can be provided to the assembly (272) of the four SPST switches (100a, 100b, 100c, 100d) to effectuate such a switching state.

The second state (State 2) of the example of Table 3 is depicted in FIG. 57A as 270a, where the TRx1-Ant1 connection is indicated as path 274a, and the TRx2-Ant2 connection is indicated as path 276a. A control signal indicated as Vc(s) in FIG. 57A and as listed in Table 3 can be provided to the assembly (272) of the four SPST switches (100a, 100b, 100c, 100d) to effectuate such a switching state.

The third state (State 3) of the example of Table 3 is depicted in FIG. 57C as 270c, where the TRx1-Ant1 connection is indicated as path 274c, and all other paths are disconnected. A control signal indicated as Vc(s) in FIG. 57C and as listed in Table 3 can be provided to the assembly (272) of the four SPST switches (100a, 100b, 100c, 100d) to effectuate such a switching state.

The fourth state (State 4) of the example of Table 3 is depicted in FIG. 57B as 270b, where the TRx1-Ant2 connection is indicated as path 276b, and the TRx2-Ant1 connection is indicated as path 274b. A control signal indicated as Vc(s) in FIG. 57B and as listed in Table 3 can be provided to the assembly (272) of the four SPST switches (100a, 100b, 100c, 100d) to effectuate such a switching state.

The fifth state (State 5) of the example of Table 3 is depicted in FIG. 57D as 270d, where the TRx1-Ant2 connection is indicated as path 276d, and all other paths are disconnected. A control signal indicated as Vc(s) in FIG. 57D and as listed in Table 3 can be provided to the assembly (272) of the four SPST switches (100a, 100b, 100c, 100d) to effectuate such a switching state.

As one can see, other switching configurations can also be implemented with the DPDT switch of FIGS. 57A-57E. It will also be understood that other switches such as 3P3T of FIGS. 55 and 56 can be controlled by control logic in a similar manner.

### Examples Related to Implementations in Products

Various examples of SOI FET devices, circuits based on such devices, and bias/coupling configurations for such devices and circuits as described herein can be implemented in a number of different ways and at different product levels. Some of such product implementations are described by way of examples.

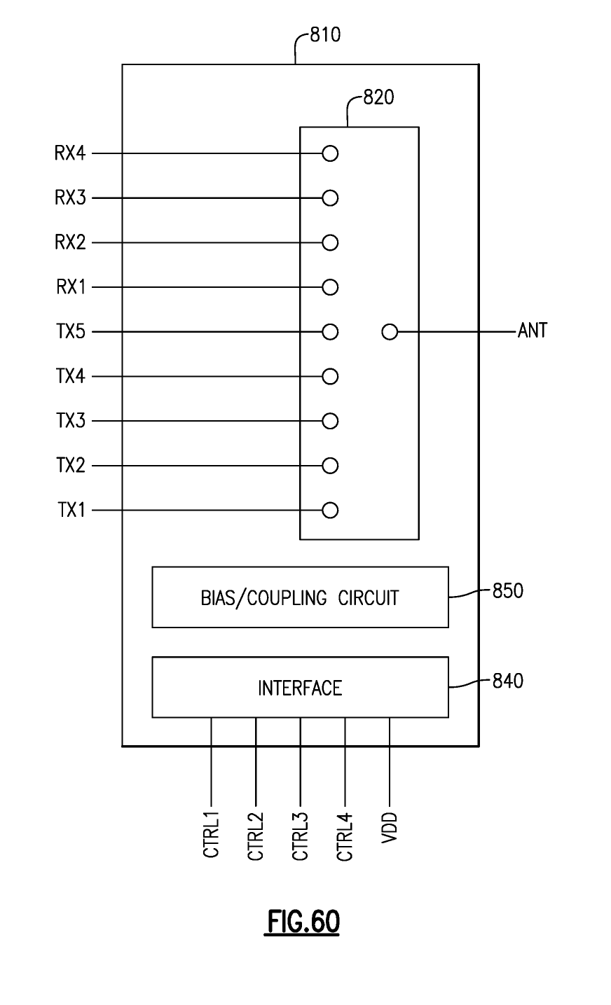

FIGS. 58A-58D depict non-limiting examples of such implementations on one or more semiconductor die. FIG. 58A shows that in some embodiments, a switch circuit 820 and a bias/coupling circuit 850 having one or more features as described herein can be implemented on a die 800. FIG. 58B shows that in some embodiments, at least some of the bias/coupling circuit 850 can be implemented outside of the die 800 of FIG. 58A.

FIG. 58C shows that in some embodiments, a switch circuit 820 having one or more features as described herein can be implemented on one die 800b, and a bias/coupling circuit 850 having one or more features as described herein can be implemented on another die 800a. FIG. 58D shows that in some embodiments, at least some of the bias/coupling circuit 850 can be implemented outside of the other die 800a of FIG. 58C.

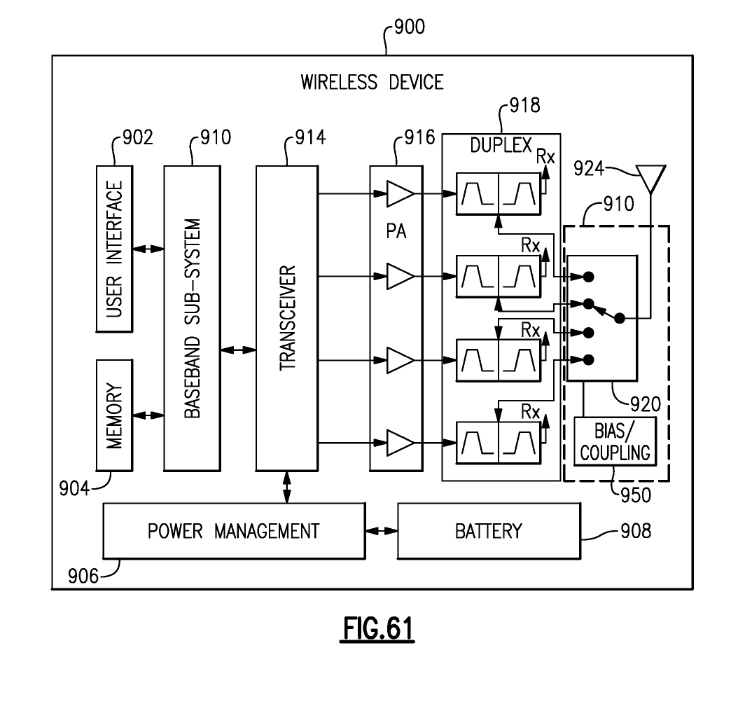

In some embodiments, one or more die having one or more features described herein can be implemented in a packaged module. An example of such a module is shown in FIGS. 59A (plan view) and 59B (side view). Although described in the context of both of the switch circuit and the bias/coupling circuit being on the same die (e.g., example configuration of FIG. 58A), it will be understood that packaged modules can be based on other configurations.

A module 810 is shown to include a packaging substrate 812. Such a packaging substrate can be configured to receive a plurality of components, and can include, for example, a laminate substrate. The components mounted on the packaging substrate 812 can include one or more die. In the example shown, a die 800 having a switching circuit 820 and a bias/coupling circuit 850 is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 833 is depicted as interconnecting the SMD 822 with an external-connection contact pad 834. In yet another example a connection path 835 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

FIG. 60 shows a schematic diagram of an example switching configuration that can be implemented in the module 810 described in reference to FIGS. 59A and 59B. In the example, the switch circuit 820 is depicted as being an SP9T switch, with the pole being connectable to an antenna and the throws being connectable to various Rx and Tx paths. Such a configuration can facilitate, for example, multi-mode multi-band operations in wireless devices. As described herein, various switching configurations (e.g., including those configured for more than one antenna) can be implemented for the switch circuit 820. As also described herein, one or more throws of such switching configurations can be connectable to corresponding path(s) configured for TRx operations.

The module 810 can further include an interface for receiving power (e.g., supply voltage VDD) and control signals to facilitate operation of the switch circuit 820 and/or the bias/coupling circuit 850. In some implementations, supply voltage and control signals can be applied to the switch circuit 820 via the bias/coupling circuit 850.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 61 depicts an example wireless device 900 having one or more advantageous features described herein. In the context of various switches and various biasing/coupling configurations as described herein, a switch 920 and a bias/coupling circuit 950 can be part of a module 910. In some embodiments, such a switch module can facilitate, for example, multi-band multi-mode operations of the wireless device 900.

In the example wireless device 900, a power amplifier (PA) assembly 916 having a plurality of PAs can provide one or more amplified RF signals to the switch 920 (via an assembly of one or more duplexers 918), and the switch 920 can route the amplified RF signal(s) to one or more antennas. The PAs 916 can receive corresponding unamplified RF signal(s) from a transceiver 914 that can be configured and operated in known manners. The transceiver 914 can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 910.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexers 918 can allow transmit and receive operations to be performed simultaneously using a common antenna (e.g., 924). In FIG. 61, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

### GENERAL COMMENTS

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio-frequency (RF) device comprising:
a field-effect transistor (FET) implemented over a substrate layer;
an electrical connection implemented to provide a substrate bias node associated with the substrate layer; and
a non-grounding circuit connected to the substrate bias node to adjust RF performance of the FET.

2-15. (canceled)

16. The RF device of claim 1 wherein the substrate layer is a part of a silicon-on-insulator (SOI) substrate.

17. The RF device of claim 16 wherein the substrate layer is a silicon handle layer.

18. The RF device of claim 16 wherein the substrate is a handle layer that includes an electrically-insulating material.

19. The RF device of claim 18 wherein the electrically-insulating material includes glass, borosilicon glass, fused quartz, sapphire, or silicon carbide.

20. (canceled)

21. The RF device of claim 16 wherein the insulator layer includes a buried oxide (BOX) layer.

22. (canceled)

23. The RF device of claim 16 wherein the electrical connection includes one or more conductive features implemented through the insulator layer.

24. The RF device of claim 23 wherein the one or more conductive features includes one or more conductive vias.

25. The RF device of claim 23 wherein the one or more conductive features includes one or more conductive trenches.

26. The RF device of claim 1 wherein the non-grounding circuit includes a bias network configured to provide a bias signal to the substrate layer.

27. The RF device of claim 26 wherein the bias signal includes a DC voltage.

28. The RF device of claim 27 wherein the bias network includes a resistance through which the DC voltage is provided to the substrate layer.

29. The RF device of claim 1 wherein the non-grounding circuit includes a coupling circuit configured to couple the substrate node with one or more nodes associated with a gate, a source, a drain and a body of the FET.

30-49. (canceled)

50. The RF device of claim 16 wherein the SOI substrate is configured such that the substrate layer is in direct engagement with an insulator layer.

51. The RF device of claim 16 wherein the SOI substrate includes an interface layer implemented between the substrate layer and an insulator layer.

52. The RF device of claim 51 wherein the interface layer includes a trap-rich layer.

53. The RF device of claim 16 wherein the SOI substrate is configured such that substrate layer includes a plurality of doped regions at or near a surface under an insulator layer.

54. The RF device of claim 53 wherein the doped regions include amorphous and high resistivity properties.

55-72. (canceled)

73. A radio-frequency (RF) switch device comprising:
a die including a substrate layer;
an RF core implemented on the die, the RF core including a plurality of field-effect transistors (FETs) configured to provide switching functionality;
an energy management (EM) core implemented on the die, the EM core configured to facilitate the switching functionality of the RF core; and
a pattern of one or more conductive features in electrical contact with the substrate layer of the die to provide a substrate node, the pattern implemented relative to a circuit element associated with the RF switch device.

74-115. (canceled)

116. A radio-frequency (RF) module comprising:
a packaging substrate configured to receive a plurality of devices; and
a switching device mounted on the packaging substrate, the switching device including a field-effect transistor (FET) implemented over a substrate layer, the switching device further including an electrical connection implemented to provide a substrate bias node associated with the substrate layer, the switching device further including a non-grounding circuit connected to the substrate bias node to adjust RF performance of the FET.

117-125. (canceled)
